(19) United States
(12) Patent Application Publication
(10) Pub. No.: US 2022/0157876 A1
(43) Pub. Date: May 19, 2022

(54) IMAGING UNIT, METHOD OF MANUFACTURING IMAGING UNIT, AND SEMICONDUCTOR DEVICE

(71) Applicant: SONY SEMICONDUCTOR SOLUTIONS CORPORATION, KANAGAWA (JP)

(72) Inventor: KOICHI MATSUMOTO, TOKYO (US)

(21) Appl. No.: 17/310,964

(22) PCT Filed: Mar. 12, 2020
(86) PCT No.: PCT/JP2020/010711

§ 371 Date: Sep. 2, 2021

(30) Foreign Application Priority Data
Mar. 15, 2019 (JP) 2019-048552

(51) Int. Cl. H01L 27/146

(52) U.S. Cl. CPC H01L 27/14636; H01L 27/14689; H01L 27/14634; H01L 27/14645

(57) ABSTRACT

An imaging unit according to an embodiment of the present disclosure includes: a first substrate; a second substrate; and a wiring line. The first substrate includes a sensor pixel on a first semiconductor substrate. The sensor pixel performs photoelectric conversion. The second substrate includes a readout circuit on a second semiconductor substrate. The readout circuit outputs a pixel signal based on electric charge outputted from the sensor pixel. The second substrate is stacked on the first substrate. The wiring line extends between the first semiconductor substrate and the second semiconductor substrate in a direction parallel with the first semiconductor substrate. The wiring line at least partially has a stack region in which a semiconductor layer and a metal layer are stacked.

### TECHNICAL FIELD

The present disclosure relates to an imaging unit having a three-dimensional structure, a method of manufacturing the imaging unit, and a semiconductor device.

### BACKGROUND ART

The introduction of a miniaturization process and improvement in packaging density have allowed an imaging unit having a two-dimensional structure to have smaller area per pixel in the past. In recent years, an imaging unit having a three-dimensional structure has been developed to allow the imaging unit to have a still smaller size and higher pixel density. In the imaging unit having the three-dimensional structure, for example, a semiconductor substrate including a plurality of sensor pixels and a semiconductor substrate including a signal processing circuit are stacked. The signal processing circuit processes a signal obtained at each of the sensor pixels.

### CITATION LIST

### Patent Literature

PTL 1: Japanese Unexamined Patent Application Publication No. 2010-245506

### SUMMARY OF THE INVENTION

Incidentally, an imaging unit having a three-dimensional structure is requested to decrease the parasitic capacitance.

It is desirable to provide an imaging unit that makes it possible to reduce the parasitic capacitance, a method of manufacturing the imaging unit, and a semiconductor device.

An imaging unit according to an embodiment of the present disclosure includes: a first substrate; a second substrate; and a wiring line. The first substrate includes a sensor pixel on a first semiconductor substrate. The sensor pixel performs photoelectric conversion. The second substrate includes a readout circuit on a second semiconductor substrate. The readout circuit outputs a pixel signal based on electric charge outputted from the sensor pixel. The second substrate is stacked on the first substrate. The wiring line extends between the first semiconductor substrate and the second semiconductor substrate in a direction parallel with the first semiconductor substrate. The wiring line at least partially has a stack region in which a semiconductor layer and a metal layer are stacked.

A method of manufacturing an imaging unit according to an embodiment of the present disclosure includes: forming a first interlayer insulating film on a first semiconductor substrate including a sensor pixel that performs photoelectric conversion; forming a semiconductor layer on the first interlayer insulating film; forming a second interlayer insulating film on the first interlayer insulating film and the semiconductor layer; forming a second semiconductor substrate including a readout circuit that outputs a pixel signal based on electric charge outputted from the sensor pixel; forming an opening in a predetermined region on the second semiconductor substrate; and forming a wiring line by stacking a metal layer on the semiconductor layer in the opening. The semiconductor layer extends in a direction parallel with the first semiconductor substrate. The opening extends through the second semiconductor substrate to the semiconductor layer. The wiring line at least partially has a stack region of the semiconductor layer and the metal layer.

A semiconductor device according to an embodiment of the present disclosure includes: a first device layer; a second device layer; and a wiring line provided between the first device layer and the second device layer. The wiring line at least partially has a stack region in which a semiconductor layer and a metal layer are stacked.

In the imaging unit, the method of manufacturing the imaging unit, and the semiconductor device according to the respective embodiments of the present disclosure, the wiring structure at least partially having the stack region makes it possible to form a wiring line between the first semiconductor substrate and the second semiconductor substrate. This decreases, for example, the number of through wiring lines extending in the normal direction of the first semiconductor substrate. The semiconductor layer and the metal layer are stacked in the stack region. Alternatively, the total height of the through wiring lines decreases.

### BRIEF DESCRIPTION OF DRAWING

FIG. 1 is a cross-sectional schematic diagram illustrating a configuration of a main portion of a semiconductor device (imaging unit) according to a first embodiment of the present disclosure in a vertical direction.

FIG. 2 is a diagram illustrating an example of a sensor pixel, a readout circuit, and a logic circuit included in the imaging unit illustrated in FIG. 1.

FIG. 3A is a schematic diagram illustrating a layout in a lower device layer of the imaging unit illustrated in FIG. 1.

FIG. 3B is a schematic diagram illustrating a layout in an upper device layer and a wiring layer of the imaging unit illustrated in FIG. 1.

FIG. 4A is a diagram illustrating an example of a process of manufacturing the imaging unit illustrated in FIG. 1.

FIG. 4B is a diagram illustrating an example of a manufacturing process subsequent to FIG. 4A.

FIG. 4C is a diagram illustrating an example of a manufacturing process subsequent to FIG. 4B.

FIG. 4D is a diagram illustrating an example of a manufacturing process subsequent to FIG. 4C.

FIG. 4E is a diagram illustrating an example of a manufacturing process subsequent to FIG. 4D.

FIG. 4F is a diagram illustrating an example of a manufacturing process subsequent to FIG. 4E.

FIG. 4G is a diagram illustrating an example of a manufacturing process subsequent to FIG. 4F.

FIG. 4H is a diagram illustrating an example of a manufacturing process subsequent to FIG. 4G.

FIG. 4I is a diagram illustrating an example of a manufacturing process subsequent to FIG. 4H.

FIG. 5 is a cross-sectional schematic diagram of a typical imaging unit in the vertical direction.

FIG. 6A is a cross-sectional schematic diagram of the imaging unit illustrated in FIG. 5 in a horizontal direction.

FIG. 6B is a cross-sectional schematic diagram of the imaging unit illustrated in FIG. 5 in the horizontal direction.

FIG. 7 is a diagram illustrating an example of a cross-sectional configuration of the imaging unit according to the first embodiment of the present disclosure in the vertical direction.

FIG. 8 is a diagram illustrating an example of a schematic configuration of the imaging unit illustrated in FIG. 7.

FIG. 9 is a diagram illustrating an example of the sensor pixel and the readout circuit illustrated in FIG. 7.

FIG. 10 is a diagram illustrating an example of the sensor pixel and the readout circuit illustrated in FIG. 7.

FIG. 11 is a diagram illustrating an example of the sensor pixel and the readout circuit illustrated in FIG. 7.

FIG. 12 is a diagram illustrating an example of the sensor pixel and the readout circuit illustrated in FIG. 7.

FIG. 13 is a diagram illustrating an example of a coupling mode between a plurality of readout circuits and a plurality of vertical signal lines.

FIG. 14 is a diagram illustrating an example of a cross-sectional configuration of the imaging unit illustrated in FIG. 7 in the horizontal direction.

FIG. 15 is a diagram illustrating an example of a cross-sectional configuration of the imaging unit illustrated in FIG. 7 in the horizontal direction.

FIG. 16 is a diagram illustrating an example of a cross-sectional configuration of the imaging unit illustrated in FIG. 7 in the horizontal direction.

FIG. 17 is a diagram illustrating an example of a wiring line layout of the imaging unit illustrated in FIG. 7 within a horizontal plane.

FIG. 18 is a diagram illustrating an example of a wiring line layout of the imaging unit illustrated in FIG. 7 within the horizontal plane.

FIG. 19 is a diagram illustrating an example of a wiring line layout of the imaging unit illustrated in FIG. 7 within the horizontal plane.

FIG. 20 is a diagram illustrating an example of a wiring line layout of the imaging unit illustrated in FIG. 7 within the horizontal plane.

FIG. 21 is a cross-sectional schematic diagram illustrating a configuration of a main portion of an imaging unit according to a second embodiment of the present disclosure in the vertical direction.

FIG. 22A is a cross-sectional schematic diagram illustrating an example of the configuration of the main portion of the imaging unit illustrated in FIG. 21 in the horizontal direction.

FIG. 22B is a cross-sectional schematic diagram illustrating an example of the configuration of the main portion of the imaging unit illustrated in FIG. 21 in the horizontal direction.

FIG. 23 is a cross-sectional schematic diagram illustrating a configuration of a main portion of an imaging unit according to a third embodiment of the present disclosure in the vertical direction.

FIG. 24 is a cross-sectional schematic diagram illustrating a configuration of a main portion of an imaging unit according to a fourth embodiment of the present disclosure in the vertical direction.

FIG. 25 is a cross-sectional schematic diagram illustrating a configuration of a main portion of an imaging unit according to a fifth embodiment of the present disclosure in the vertical direction.

FIG. 26 is a diagram illustrating an example of a cross-sectional configuration of an imaging unit according to a modification example 1 of the present disclosure in the vertical direction.

FIG. 27 is a diagram illustrating an example of a cross-sectional configuration of an imaging unit according to a modification example 2 of the present disclosure in the vertical direction.

FIG. 28 is a diagram illustrating an example of a cross-sectional configuration of an imaging unit according to a modification example 3 of the present disclosure in the horizontal direction.

FIG. 29 is a diagram illustrating another example of a cross-sectional configuration of the imaging unit according to the modification example 3 of the present disclosure in the horizontal direction.

FIG. 30 is a diagram illustrating an example of a cross-sectional configuration of an imaging unit according to a modification example 4 of the present disclosure in the horizontal direction.

FIG. 31 is a diagram illustrating an example of a cross-sectional configuration of the imaging unit according to the modification example 4 of the present disclosure in the horizontal direction.

FIG. 32 is a diagram illustrating an example of a cross-sectional configuration of an imaging unit according to a modification example 5 of the present disclosure in the horizontal direction.

FIG. 33 is a diagram illustrating another example of a cross-sectional configuration of an imaging unit according to a modification example 6 of the present disclosure in the horizontal direction.

FIG. 34 is a diagram illustrating an example of a circuit configuration of an imaging unit according to a modification example 7 of the present disclosure.

FIG. 35 is a diagram illustrating an example in which an imaging unit according to a modification example 8 of the present disclosure in FIG. 34 includes three substrates that are stacked.

FIG. 36 is a diagram illustrating an example in which a logic circuit according to a modification example 9 of the present disclosure is separately formed in a substrate provided with a sensor pixel and a substrate provided with a readout circuit.

FIG. 37 is a diagram illustrating an example in which a logic circuit according to a modification example 10 of the present disclosure is formed on a third substrate.

FIG. 38 is a diagram illustrating an example of a schematic configuration of an imaging system including the imaging unit according to any of the embodiment described above and the modification examples thereof.

FIG. 39 is a diagram illustrating an example of an imaging procedure in the imaging system in FIG. 38.

FIG. 40 is a block diagram depicting an example of schematic configuration of a vehicle control system.

FIG. 41 is a diagram of assistance in explaining an example of installation positions of an outside-vehicle information detecting section and an imaging section.

FIG. 42 is a view depicting an example of a schematic configuration of an endoscopic surgery system.

FIG. 43 is a block diagram depicting an example of a functional configuration of a camera head and a camera control unit (CCU).

### MODES FOR CARRYING OUT THE INVENTION

The following describes an embodiment of the present disclosure in detail with reference to the drawings. The following description is a specific example of the present disclosure, but the present disclosure is not limited to the following modes. In addition, the present disclosure is not also limited to the disposition, dimensions, dimension ratios, and the like of the respective components illustrated in the respective diagrams. It is to be noted that description is given in the following order.
1. First Embodiment (An example in which a wiring line having a stacked structure is provided between a first semiconductor substrate and a second semiconductor substrate)
1-1. Configuration of Semiconductor Device
1-2. Method of Manufacturing Semiconductor Device
1-3. Configuration of Imaging Unit
1-4. Workings and Effects
2. Second Embodiment (An example in which a wiring line partially having a stacked structure is provided between a first semiconductor substrate and a second semiconductor substrate)
3. Third Embodiment (An example in which a wiring line is directly provided on a gate of a transfer transistor)
4. Fourth Embodiment (An example in which a gate of a transfer transistor and a wiring line are integrally formed)
5. Fifth Embodiment (An example in which wiring lines each having a stacked structure are provided between a first semiconductor substrate and a second semiconductor substrate and between the second semiconductor substrate and a third semiconductor substrate)
6. Modification Examples
6-1. Modification Example 1 (An example in which vertical TG is used)
6-2. Modification Example 2 (An example in which Cu-Cu junction is used at a panel outer edge)
6-3. Modification Example 3 (An example in which FD is provided for each of sensor pixels)
6-4. Modification Example 4 (An example in which an offset is provided between a sensor pixel and a readout circuit)
6-5. Modification Example 5 (An example in which a silicon substrate provided with a readout circuit has an island shape)
6-6. Modification Example 6 (An example in which a silicon substrate provided with a readout circuit has an island shape)
6-7. Modification Example 7 (An example in which a column signal processing circuit includes a typical column ADC circuit)
6-8. Modification Example 8 (An example in which an imaging unit includes three substrates that are stacked)
6-9. Modification Example 9 (An example in which a logic circuit is provided on a first substrate and a second substrate)
6-10. Modification Example 10 (An example in which a logic circuit is provided on a third substrate)
7. Application Examples
8. Practical Application Examples

### 1. First Embodiment

### 1-1. Configuration of Semiconductor Device

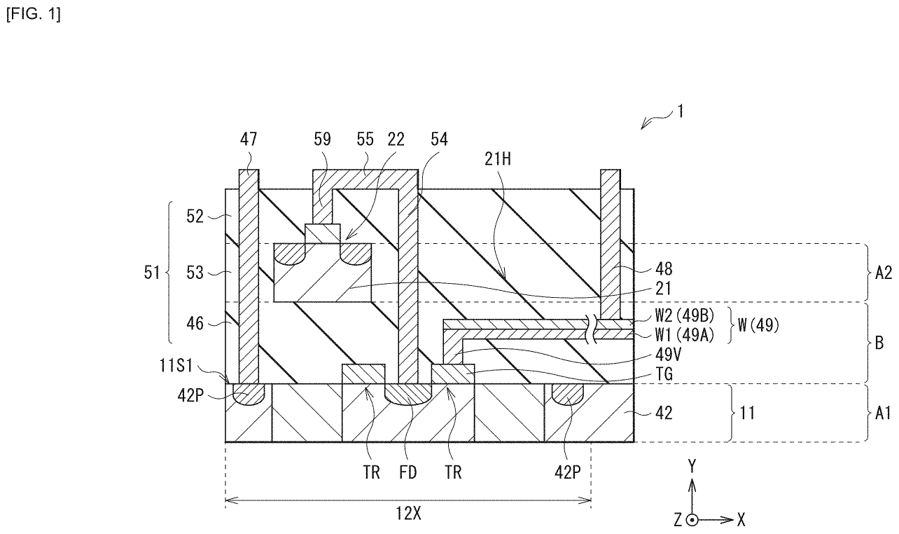

FIG. 1 schematically illustrates an example of a cross-sectional configuration of the main portion of a semiconductor device (a semiconductor device 1) according to a first embodiment of the present disclosure in the vertical direction (the Y axis direction). The semiconductor device 1 is a semiconductor device having a three-dimensional structure in which a device layer A1 and a device layer A2 are stacked. The semiconductor device 1 has a configuration in which a wiring line W is provided in a wiring layer B between the device layer A1 and the device layer A2. A semiconductor layer W1 and a metal layer W2 are stacked in the wiring line W. This semiconductor device 1 is applicable, for example, to an imaging unit having a three-dimensional structure. Description is therefore given by using a configuration of an imaging unit 1A described below. The detailed configuration of the imaging unit 1A is described below.

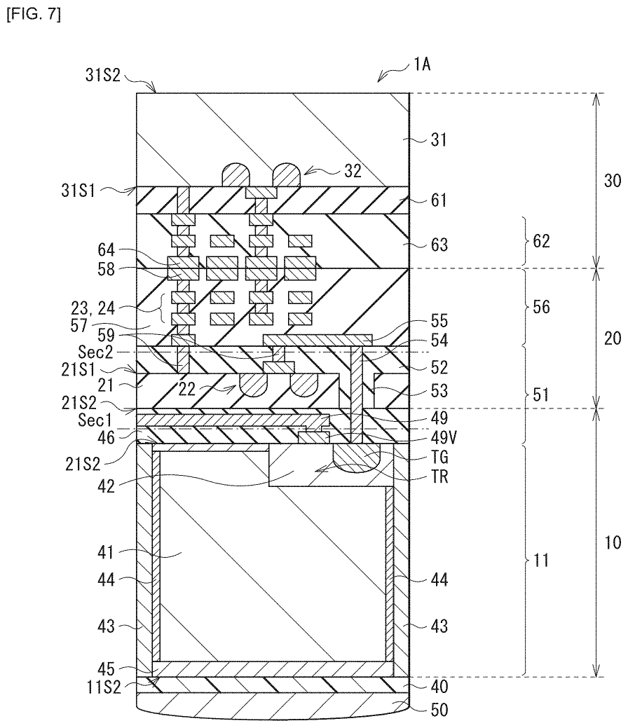

In the imaging unit 1A, a first substrate 10, a second substrate 20, and a third substrate 30 are stacked (see FIG. 7). The first substrate 10 includes a sensor pixel 12 on a semiconductor substrate 11. The sensor pixel 12 performs photoelectric conversion. The second substrate 20 includes a readout circuit 22 on a semiconductor substrate 21. The readout circuit 22 outputs an image signal based on electric charge outputted from the sensor pixel 12. The third substrate 30 includes a logic circuit 32 (a signal processing circuit). This semiconductor substrate 11 corresponds to the device layer A1 described above and the semiconductor substrate 21 corresponds to the device layer A2 described above. In a stacked body of the first substrate 10 and the second substrate 20 of the semiconductor device 1, there is provided a wiring line 49 between the semiconductor substrate 11 and the semiconductor substrate 21. The wiring line 49 extends in the direction parallel with the semiconductor substrate 11. A semiconductor layer 49A and a metal layer 49B are stacked in the wiring line 49. These semiconductor layer 49A, metal layer 49B, and wiring line 49 respectively correspond to the semiconductor layer W1, the metal layer W2, and the wiring line W described above.

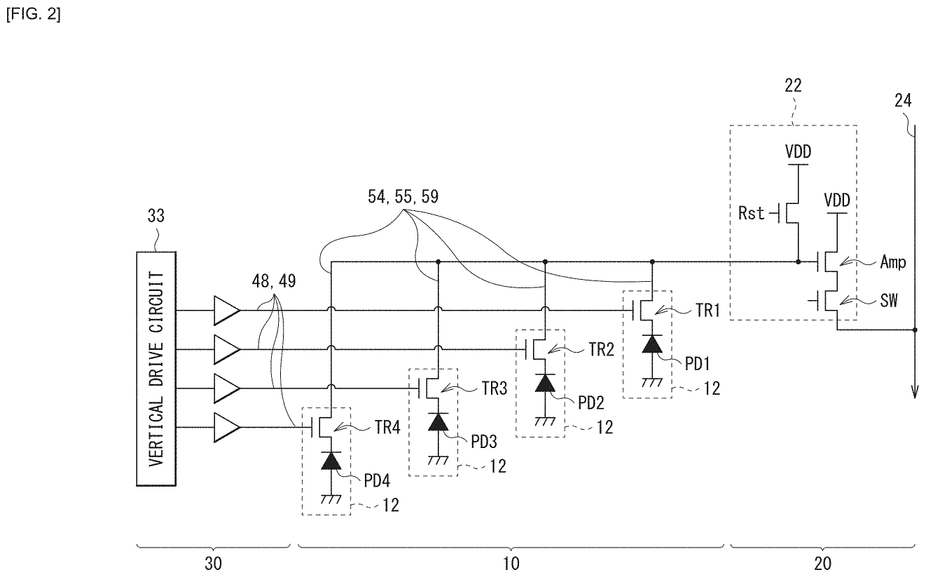

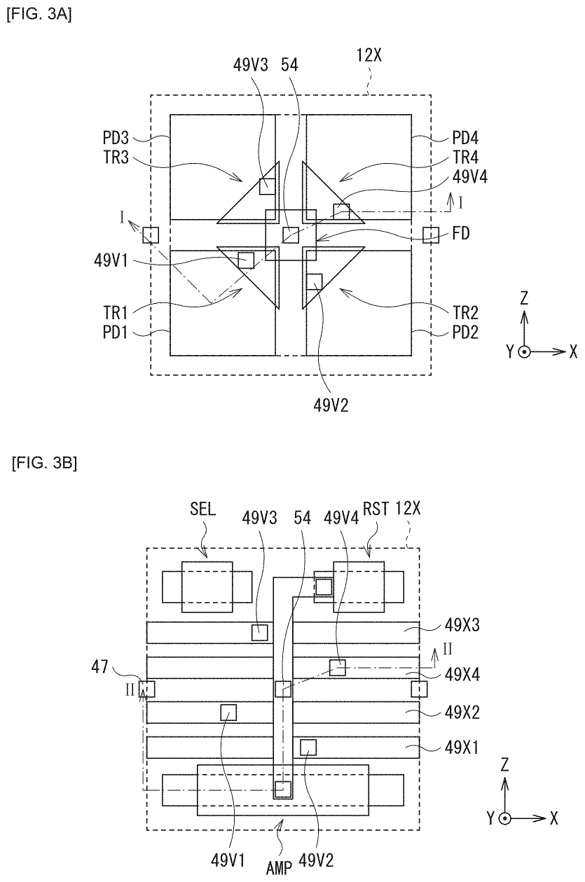

FIG. 2 illustrates an example of the sensor pixel 12, the readout circuit 22, and the logic circuit 32 (a vertical drive circuit 33). FIG. 3A illustrates a layout in the device layer A1 and FIG. 3B illustrates a layout in the device layer A2 and the wiring layer B. Each of FIGS. 3A and 3B exemplifies a configuration of the 2×2 or four sensor pixels 12 that share one floating diffusion FD. A unit region corresponding to the 2×2 or four sensor pixels 12 that share this one floating diffusion FD is referred to as unit region 12X for the sake of convenience. It is to be noted that the cross section illustrated in FIG. 1 corresponds to an I-I line and an II-II line illustrated in FIGS. 3A and 3B. However, the I-I line and the II-II line are illustrated for the sake of convenience. The I-I line or the II-II line does not completely match FIG. 1.

The first substrate 10 includes the plurality of sensor pixels 12 on the semiconductor substrate 11. Each of the plurality of sensor pixels 12 performs photoelectric conversion. The semiconductor substrate 11 corresponds to specific examples of a “first semiconductor substrate” and a “first device layer” according to the present disclosure. The plurality of sensor pixels 12 is provided in matrix in a pixel region 13 on the first substrate 10. The first substrate 10 shares the floating diffusion FD between the four sensor pixels 12. The floating diffusion FD temporarily holds electric charge outputted from photodiodes PD. Each of the sensor pixels 12 includes mutually common components. The second substrate 20 includes the one readout circuit 22 for every four sensor pixels 12 on the semiconductor substrate 21. The readout circuit 22 outputs a pixel signal based on electric charge outputted from each of the sensor pixels 12. The semiconductor substrate 21 corresponds to specific examples of a “second semiconductor substrate” and a “second device layer” according to the present disclosure. The third substrate 30 includes the logic circuit 32 on a semiconductor substrate 31. The logic circuit 32 processes a pixel signal. The semiconductor substrate 31 corresponds to a specific example of a “third semiconductor substrate” according to the present disclosure. The logic circuit 32 includes, for example, the vertical drive circuit 33 as illustrated in FIG. 2.

Each of the sensor pixels 12 includes, for example, the photodiode PD, a transfer transistor TR electrically coupled to the photodiode PD, and a floating diffusion FD that temporarily holds electric charge outputted from the photodiode PD through the transfer transistor TR. The cathode of the photodiode PD is electrically coupled to the source of the transfer transistor TR and the anode of the photodiode PD is electrically coupled to a reference potential line (e.g., ground). The drain of the transfer transistor TR is electrically coupled to the floating diffusion FD and the gate of the transfer transistor TR is electrically coupled to the vertical drive circuit 33, for example, through the pixel drive line 23 described below.

The floating diffusion FD shared by the four sensor pixels 12 is electrically coupled to the input end of the common readout circuit 22. The readout circuit 22 includes, for example, a reset transistor RST, a selection transistor SEL, and an amplification transistor AMP. The source of the reset transistor RST (the input end of the readout circuit 22) is electrically coupled to the floating diffusion FD and the drain of the reset transistor RST is electrically coupled to a power supply line VDD and the drain of the amplification transistor AMP. The source of the amplification transistor AMP is electrically coupled to the drain of the selection transistor SEL and the gate of the amplification transistor AMP is electrically coupled to the source of the reset transistor RST. In the present embodiment, as described above, the first substrate 10 includes the photodiode PD and the transfer transistor TR for each of the sensor pixels 12 and shares the floating diffusion FD between the four sensor pixels 12. Four transfer gates TG provided to the respective sensor pixels 12 in the unit region 12X are disposed to surround the one floating diffusion FD. In addition, the reset transistor RST and the selection transistor SEL are disposed along one side of the unit region 12X and the amplification transistor AMP is disposed along the opposed side of the unit region 12X as illustrated in FIG. 3B.

Next, a cross-sectional configuration of the semiconductor device 1 in the vertical direction is described with reference to FIG. 1. The semiconductor device 1 has a configuration in which the first substrate 10 and the second substrate 20 are stacked in this order as described above.

The first substrate 10 includes an insulating layer 46 that is stacked on the front surface (a surface 11S1) of the semiconductor substrate 11 as a portion of an interlayer insulating film 51. The semiconductor substrate 11 includes a silicon substrate. The semiconductor substrate 11 includes, for example, a p well 42 and a photodiode PD41. The p well 42 includes a p-type semiconductor region. The photodiode PD41 includes a semiconductor region of a different electric conductivity type (specifically, n-type) from that of the p well 42. The semiconductor substrate 11 includes, in the p well 42, the floating diffusion FD as a semiconductor region of an electric conductivity type (specifically, n-type) different from that of the p well 42. In addition, the semiconductor substrate 11 includes a contact diffusion layer 42P in the p well 42. The contact diffusion layer 42P is of the same electric conductivity type (specifically, p-type) as that of the p well 42 and has higher impurity concentration than that of the p well 42. In other words, the first substrate 10 has a configuration in which the transfer transistor TR, the floating diffusion FD, and the contact diffusion layer 42P are provided on a portion of the semiconductor substrate 11 on the surface 11S1 side (the opposite side to the light incidence surface or the second substrate 20 side).

The second substrate 20 includes an insulating layer 52 that is stacked on the semiconductor substrate 21 as a portion of the interlayer insulating film 51. The semiconductor substrate 21 includes a silicon substrate. The second substrate 20 includes the one readout circuit 22 for every four sensor pixels 12. The second substrate 20 has a configuration in which the readout circuit 22 is provided on a portion of the semiconductor substrate 21 on the front surface (a surface 21S1) side. The second substrate 20 further includes an insulating layer 53 in the same layer as the semiconductor substrate 21 as a portion of the interlayer insulating film 51. The second substrate 20 includes, for example, a coupling section 59 in the insulating layer 52. The coupling section 59 is coupled to the readout circuit 22 (specifically, the reset transistor RST). The second substrate 20 further includes, for example, a coupling wiring line 55 on the insulating layer 52. The coupling wiring line 55 is for coupling the coupling section 59 and a through wiring line 54 described below. This electrically couples the floating diffusion FD and the readout circuit 22.

A stacked body including the first substrate 10 and the second substrate 20 includes the through wiring line 54 provided in the interlayer insulating film 51. The through wiring line 54 corresponds to a specific example of a “first through wiring line” according to the present disclosure. The stacked body described above includes the one through wiring line 54 for each of the sensor pixels 12. The through wiring line 54 extends in the normal direction (the Y axis direction) of the semiconductor substrate 21 and is provided to penetrate a portion of the interlayer insulating film 51 that includes the insulating layer 53. The first substrate 10 and the second substrate 20 are electrically coupled to each other by the through wiring line 54. Specifically, the through wiring line 54 electrically couples the floating diffusion FD and the readout circuit 22 along with the coupling wiring line 55 and the coupling section 59.

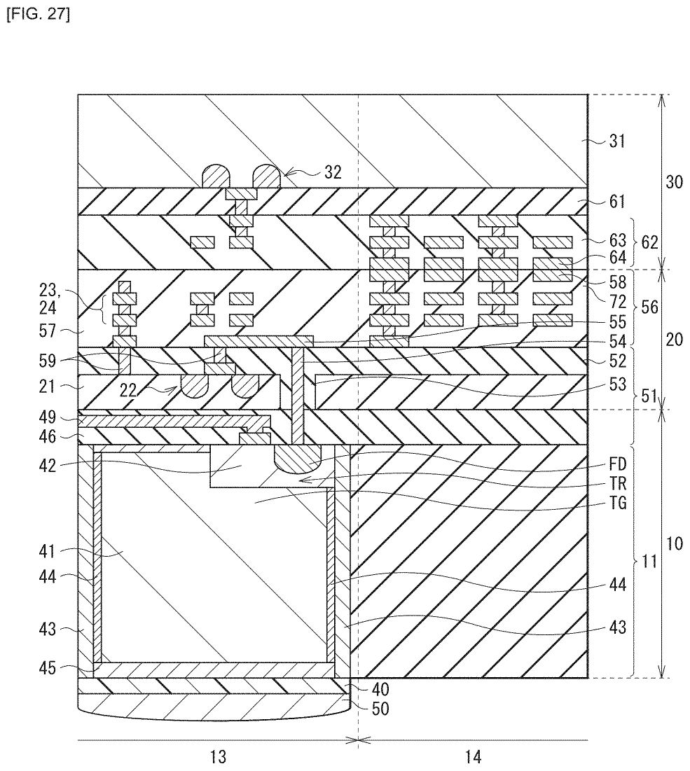

The stacked body including the first substrate 10 and the second substrate 20 further includes through wiring lines 47 and 48 provided in the interlayer insulating film 51. The stacked body described above includes, for example, the one or more through wiring lines 47 and the one through wiring line 48 for every four sensor pixels 12. Each of the through wiring lines 47 and 48 extends in the normal direction of the semiconductor substrate 21 and is provided to penetrate a portion of the interlayer insulating film 51 that includes the insulating layer 53. The first substrate 10 and the second substrate 20 are electrically coupled to each other by the through wiring lines 47 and 48. Specifically, the through wiring line 47 electrically couples the contact diffusion layer 42P of the semiconductor substrate 11 and a wiring line (specifically, a vertical signal line 24) in the second substrate 20. Although described in detail below, one end of the through wiring line 48 is provided between the semiconductor substrate 11 and the semiconductor substrate 21 and is coupled to the wiring line 49 extending in the direction parallel with the semiconductor substrate 11. The other end is coupled to a wiring line (specifically, the pixel drive line 23) in the second substrate 20 and electrically couples the transfer gate TG of the transfer transistor TR and the vertical drive circuit 33. This through wiring line 48 is formed, for example, in a peripheral region 14 illustrated in FIG. 27 described below.

The stacked body including the first substrate 10 and the second substrate 20 further includes the wiring line 49 in the interlayer insulating film 51. The wiring line 49 corresponds to the wiring line W described above and corresponds to a specific example of a “wiring line” according to the present disclosure. Specifically, the wiring line 49 is provided in the insulating layer 46 between the semiconductor substrate 11 and the semiconductor substrate 21. The semiconductor substrate 11 is included in the first substrate 10. The semiconductor substrate 21 is included in the second substrate 20. The wiring line 49 electrically couples the transfer gate TG of the transfer transistor TR and the vertical drive circuit 33 along with a via 49V and the through wiring line 48. The one wiring line 49 is provided for each of the four sensor pixels 12 disposed in the unit region 12X. In other words, four wiring lines 49X1, 49X2, 49X3, and 49X4 are disposed side by side in a strip shape, for example, between the reset transistor RST and the selection transistor SEL and the amplification transistor AMP in the unit region 12X as illustrated in FIG. 3B. It is possible to independently form the respective wiring lines 49X1, 49X2, 49X3, and 49X4 by providing and shifting vias 49V1, 49V2, 49V3, and 49V4. The vias 49V1, 49V2, 49V3, and 49V4 respectively couples the transfer gates TG of respective transfer transistors TR1, TR2, TR3, and TR4 and the wiring lines 49X1, 49X2, 49X3, and 49X4.

The wiring line 49 has a stacked structure in which the semiconductor layer 49A and the metal layer 49B are stacked in order from the semiconductor substrate 11 side. Examples of a material of the semiconductor layer 49A include a polymer, an amorphous solid, or a single crystal of Si, Ge, SiGe, SiC, ZnSe, GaAs, GaP, InP, InN, GaN, InGaN, GaAlAs, IGaAs, GaInNAs, InGaAlP, ZnO, IGZO, MoS₂, MoSe₂, MoTe₂, WS₂, WSe₂, WTe₂, ZrS₂, ZrSe₂, ZrTe₂, HfS₂, HfSe₂, HfTe₂, graphene, phospherene, and a carbon nanotube. Examples of a material of the metal layer 49B include one or two or more of tungsten (W), aluminum (Al), cobalt (Co), nickel (Ni), and platinum (Pt) or a compound (a silicide) of any of the metals described above and silicon (Si). The wiring line 49 and the transfer gate TG is coupled through the via 49V. A material of the via 49V includes the semiconductors mentioned for the semiconductor layer 49A. The wiring line 49 and the vertical drive circuit 33 are coupled through the through wiring line 48. A material of the through wiring line 48 includes the metals mentioned for the metal layer 49B.

### 1-2. Method of Manufacturing Semiconductor Device

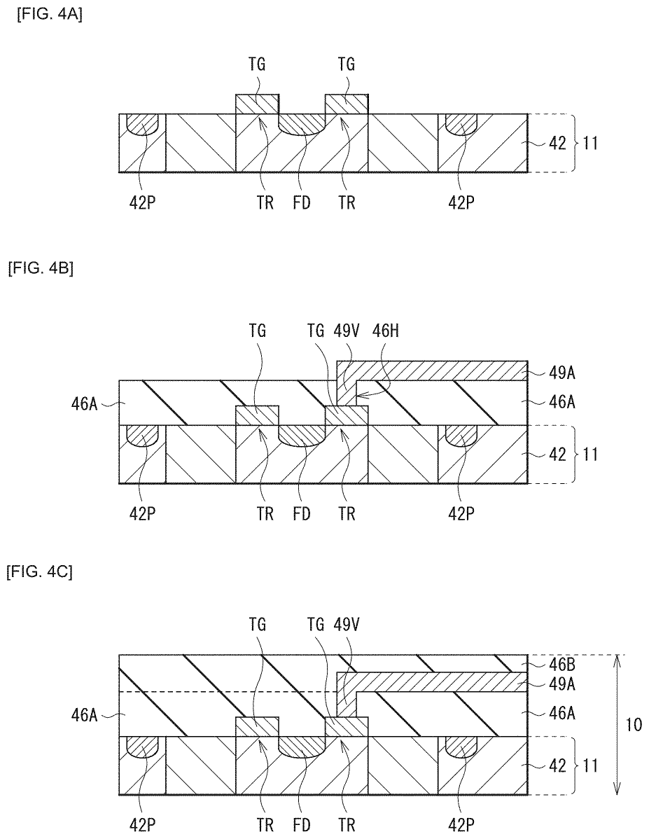

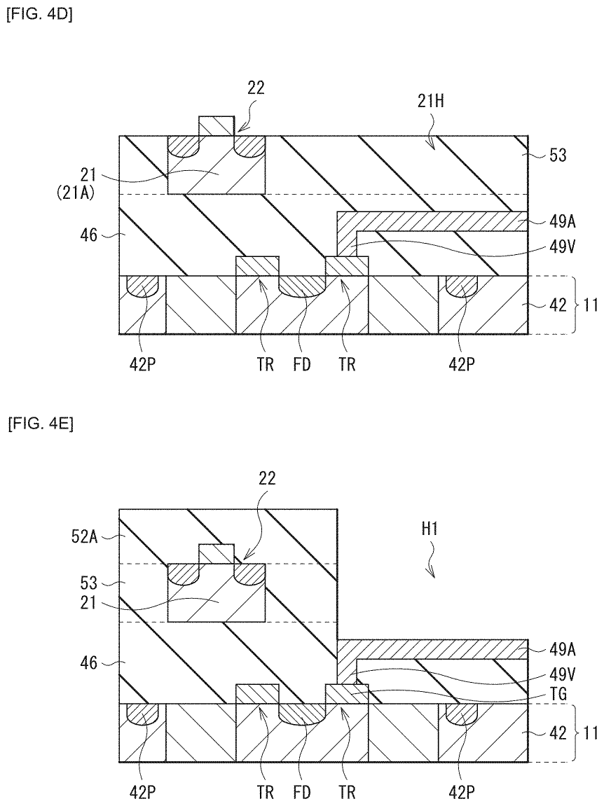

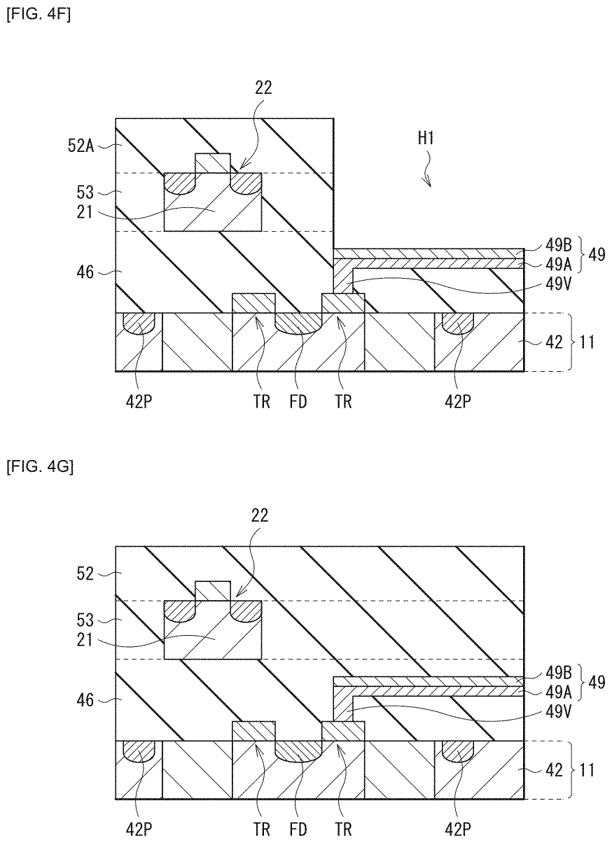

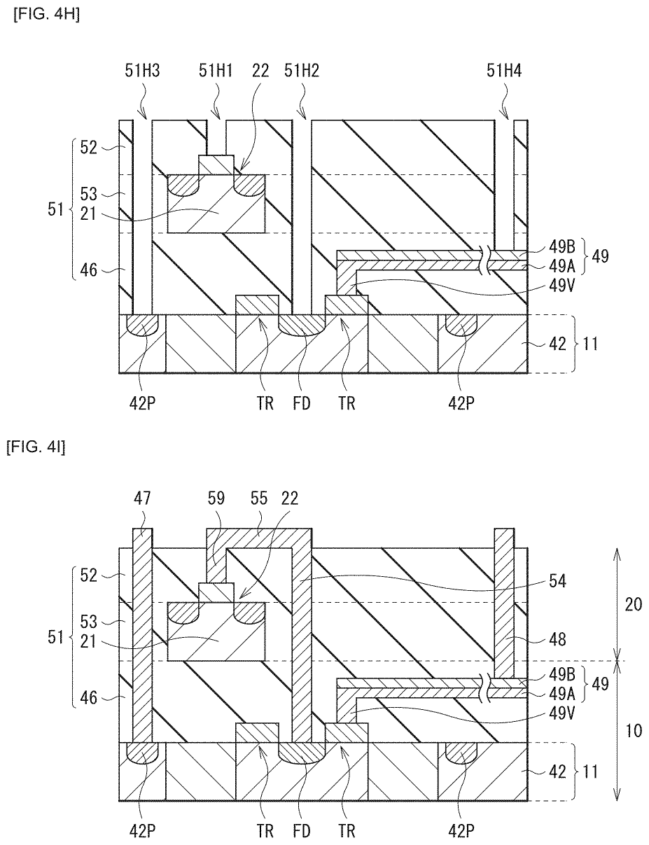

Next, a method of manufacturing the semiconductor device 1 is described. Each of FIGS. 4A to 4F illustrates an example of a process of manufacturing the semiconductor device 1.

First, the p well 42, an element separation section 43, and the p well layer 44 are formed on the semiconductor substrate 11. Next, the photodiode PD41, the transfer transistor TR, and the floating diffusion FD are formed on the semiconductor substrate 11 (FIG. 4A). This forms the sensor pixel 12 on the semiconductor substrate 11. Subsequently, an insulating layer 46A is formed on the semiconductor substrate 11. Next, an opening 46H that extends through the insulating layer 46A is provided on the transfer gate (TG) of the transfer transistor TR. After that, the semiconductor layer 49A is formed along with the via 49V by using, for example, polysilicon (FIG. 4B). The via 49V fills the opening 46H. The semiconductor layer 49A extends in the direction parallel with the semiconductor substrate 11. Subsequently, an insulating layer 46B is formed on the insulating layer 46A and the semiconductor layer 49A (FIG. 4C). In this way, the first substrate 10 is formed.

Next, the semiconductor substrate 21 is bonded onto the first substrate 10. After that, an opening 21H is formed that extends through the semiconductor substrate 21. The semiconductor substrate 21 is separated into a plurality of blocks 21A. After that, the insulating layer 53 is formed to fill the opening 21H. Subsequently, the readout circuit 22 including the amplification transistor AMP and the like is formed in each of the blocks 21A of the semiconductor substrate 21 (FIG. 4D). Next, an insulating layer 52A is formed on the semiconductor substrate 21. After that, an opening H1 that extends through the insulating layers 52A, 53, and 46 is formed at a corresponding position on the semiconductor layer 49A (FIG. 4E).

Subsequently, the metal layer 49B is formed on the semiconductor layer 49A (FIG. 4F). It is possible to form the metal layer 49B by using silicidation. For example, cobalt (Co) or nickel (Ni) is sputtered, for example, on the semiconductor layer 49A. After that, annealing treatment is performed. After that, an unreacted portion is removed and annealing treatment is performed again. This forms the metal layer 49B on the semiconductor layer 49A. In addition, the metal layer 49B may be formed by using selective CVD. It is possible to selectively form the metal layer 49B including a W film on the semiconductor layer 49A by selective CVD using, for example, tungsten fluoride (WF₆) and silane (SiH₄).

Next, an insulating layer is formed on the insulating layer 52A and the metal layer 49B to fill the opening H1, thereby forming the insulating layer 52. In this way, the interlayer insulating film 51 including the insulating layers 46, 52, and 53 is formed (FIG. 4G). Subsequently, through holes 51H1, 51H2, 51H3, and 51H4 are formed in the interlayer insulating film 51 (FIG. 4H). Specifically, the through hole 51H1 that extends through the insulating layer 52 is formed in a portion of the interlayer insulating film 51 that is opposed to the readout circuit 22. In addition, the through hole 51H2 that extends through the interlayer insulating film 51 is formed in a portion of the interlayer insulating film 51 that is opposed to the floating diffusion FD. Further, the through hole 51H3 that extends through the interlayer insulating film 51 is formed in a portion of the interlayer insulating film 51 opposed to the contact diffusion layer 42P. Still further, the through hole 51H4 that extends through the interlayer insulating film 51 is formed in a portion opposed to the wiring line 49.

Next, the through wiring line 54 is formed in the through hole 51H1 and the coupling section 59 is formed in the through hole 51H2 by filling each of the through holes 51H1, 51H2, 51H3, and 51H4 with an electrically conductive material. In addition, the through wiring line 47 is formed in the through hole 51H3 and the through wiring line 48 is formed in the through hole 51H4. Subsequently, the coupling wiring line 55 that electrically couples the through wiring line 54 and the coupling section 59 to each other is formed on the insulating layer 52 (FIG. 4I). In this way, the second substrate 20 is formed and the semiconductor device 1 illustrated in FIG. 1 is manufactured.

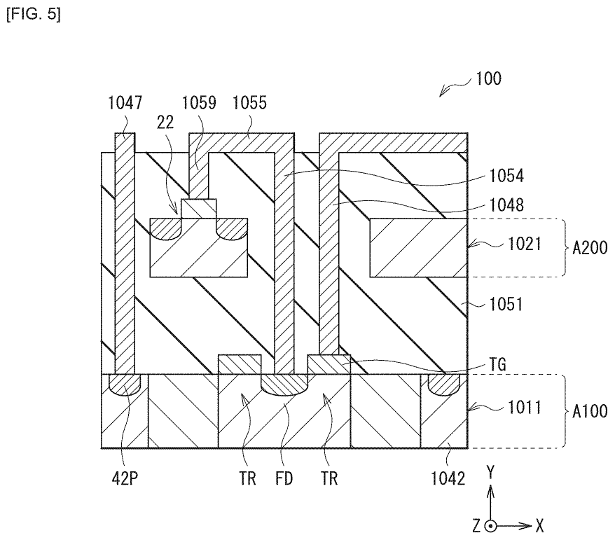

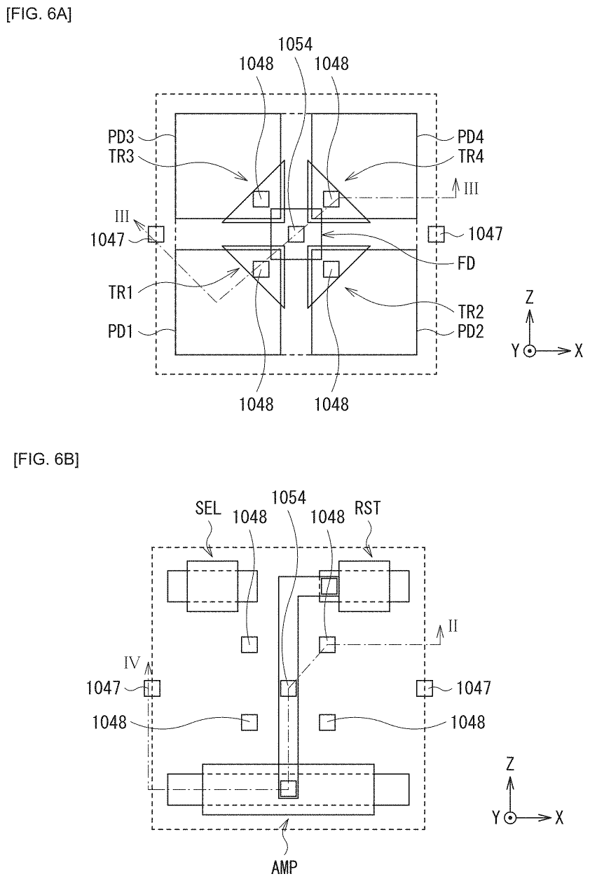

FIG. 5 schematically illustrates a cross-sectional configuration of a semiconductor device 100 in the vertical direction (the Y axis direction). The semiconductor device 100 corresponds to the semiconductor device 1 illustrated in FIG. 1 and has a typical three-dimensional structure. FIG. 6A illustrates a layout in a device layer A100 and FIG. 6B illustrates a layout in a device layer A200. It is to be noted that the cross section illustrated in FIG. 5 corresponds to an III-III line and an IV-IV line illustrated in FIGS. 6A and 6B. However, the III-III line and the IV-IV line are illustrated for the sake of convenience. The III-III line or the IV-IV line does not completely match FIG. 1.

As illustrated in each of FIGS. 5, 6A, and 6B, in the semiconductor device 100 having a typical three-dimensional structure, a plurality (four in the semiconductor device 100) of through wiring line 1048 is formed around a through wiring line 1054 to extend in parallel. The through wiring line 1054 electrically couples the floating diffusion FD and a readout circuit 1022. The plurality of through wiring lines 1048 electrically couples the transfer gate TG of the transfer transistor TR and a vertical drive line (not illustrated). This increases the capacitance (the parasitic capacitance) between the through wiring line 1054 and the through wiring lines 1048.

In contrast, in the present embodiment, the wiring line W is formed in the wiring layer B between the device layer A1 and the device layer A2. The wiring line W extends in the direction parallel with the device layer A1. The semiconductor layer W1 and the metal layer W2 are stacked in the wiring line W. This decreases the total number of through wiring lines extending in the stack direction of the device layer A1 and the device layer A2. This makes it possible to reduce the parasitic capacitance between the through wiring lines.

### 1-3. Configuration of Imaging Unit

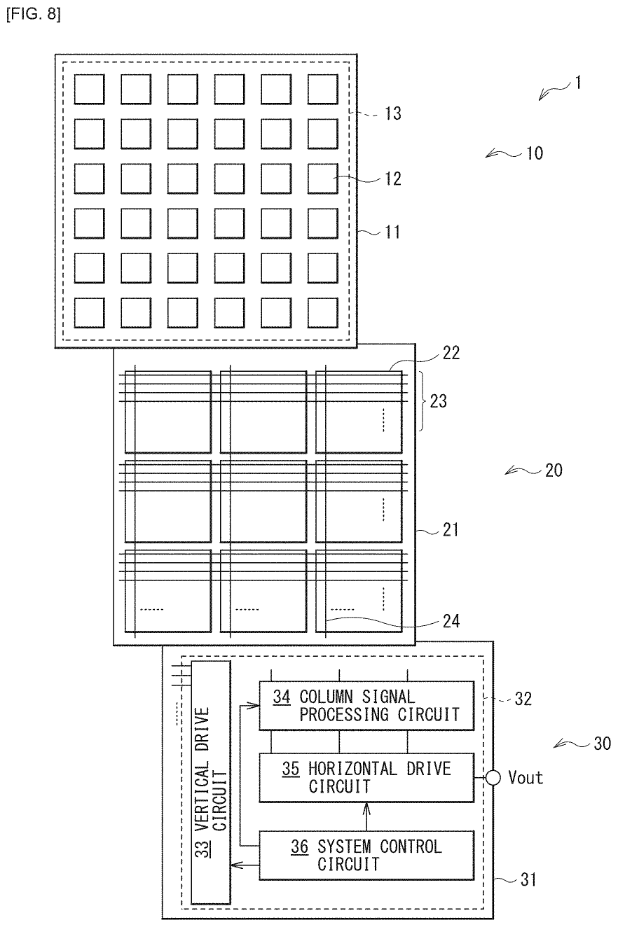

Next, the imaging unit 1A to which the configuration of the semiconductor device 1 described above is applied is described in detail. FIG. 7 illustrates an example of a cross-sectional configuration of the imaging unit (the imaging unit 1A) according to the first embodiment of the present disclosure in the vertical direction. FIG. 8 illustrates an example of a schematic configuration of the imaging unit 1A illustrated in FIG. 7. In the imaging unit 1A according to the present embodiment, three substrates (the first substrate 10, the second substrate 20, and the third substrate 30) are stacked in this order.

As described above, the first substrate 10 includes the plurality of sensor pixels 12 on the semiconductor substrate 11. Each of the plurality of sensor pixels 12 performs photoelectric conversion. The plurality of sensor pixels 12 is provided in matrix in a pixel region 13 on the first substrate 10. The first substrate 10 shares the floating diffusion FD between the four sensor pixels 12. The floating diffusion FD temporarily holds electric charge outputted from the photodiodes PD. The second substrate 20 includes the one readout circuit 22 for every four sensor pixels 12 on the semiconductor substrate 21. The readout circuit 22 outputs a pixel signal based on electric charge outputted from each of the sensor pixels 12. The second substrate 20 includes a plurality of pixel drive lines 23 extending in the row direction and a plurality of vertical signal lines 24 extending in the column direction. It is to be noted that the plurality of pixel drive lines 23 may be provided, for example, on the first substrate 10 side (e.g., in the interlayer insulating film 51 between the semiconductor substrate 11 and the semiconductor substrate 21). The third substrate 30 includes the logic circuit 32 on the semiconductor substrate 31. The logic circuit 32 processes a pixel signal. The semiconductor substrate 31 corresponds to a specific example of the “third semiconductor substrate” according to the present disclosure. The logic circuit 32 includes, for example, a vertical drive circuit 33, a column signal processing circuit 34, a horizontal drive circuit 35, and a system control circuit 36. The logic circuit 32 (specifically, the horizontal drive circuit 35) outputs an output voltage Vout for each of the sensor pixels 12 to the outside. In the logic circuit 32, for example, a low resistance region that includes a silicide and is formed by using Salicide (Self Aligned silicide) process such as CoSi₂ and NiSi may be formed on the surface of an impurity diffusion region in contact with a source electrode and a drain electrode.

The vertical drive circuit 33 selects, for example, the plurality of sensor pixels 12 row by row in order. The column signal processing circuit 34 performs, for example, a correlated double sampling (Correlated Double Sampling: CDS) process on a pixel signal outputted from each of the sensor pixels 12 in a row selected by the vertical drive circuit 33. The column signal processing circuit 34 performs, for example, the CDS process, thereby extracting the signal level of the pixel signal. The column signal processing circuit 34 holds pixel data corresponding to the amount of light received by each of the sensor pixels 12. The horizontal drive circuit 35 outputs, for example, the pieces of pixel data held in the column signal processing circuit 34 to the outside in order. The system control circuit 36 controls, for example, the driving of each of the blocks (the vertical drive circuit 33, the column signal processing circuit 34, and the horizontal drive circuit 35) in the logic circuit 32.

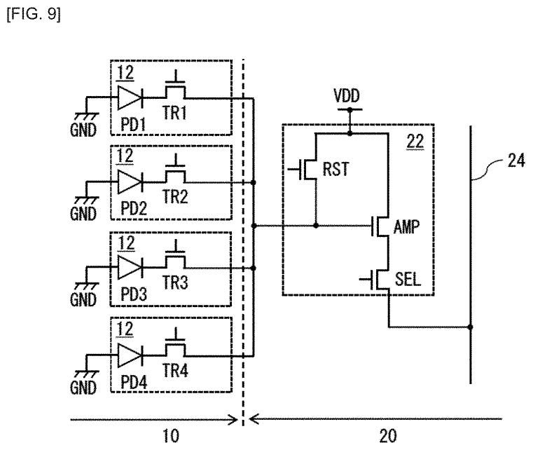

FIG. 9 illustrates examples of the sensor pixel 12 and the readout circuit 22. The following describes a case where the four sensor pixels 12 share the one floating diffusion FD and the one readout circuit 22 as illustrated in FIG. 3A. Here, the “share” means that outputs of the four sensor pixels 12 are inputted to the common floating diffusion FD and readout circuit 22.

Each of the sensor pixels 12 includes mutually common components. In FIG. 9, to distinguish components of the respective sensor pixels 12 from each other, an identification number (1, 2, 3, or 4) is assigned to the end of the symbol of a component of each of the sensor pixels 12. In a case where the components of the respective sensor pixels 12 have to be distinguished from each other, the following assigns an identification number at the end of the symbol of a component of each of the sensor pixels 12. However, in a case where there is no need to distinguish the components of the respective sensor pixels 12 from each other, an identification number at the end of the symbol of a component of each of the sensor pixels 12 is omitted.

Each of the sensor pixels 12 includes, for example, the photodiode PD, the transfer transistor TR electrically coupled to the photodiode PD, and the floating diffusion FD that temporarily holds electric charge outputted from the photodiode PD through the transfer transistor TR. The photodiode PD corresponds to a specific example of a “photoelectric conversion element” according to the present disclosure. The photodiode PD performs photoelectric conversion to generate electric charge corresponding to the amount of received light. As described above, the cathode of the photodiode PD is electrically coupled to the source of the transfer transistor TR and the anode of the photodiode PD is electrically coupled to a reference potential line (e.g., ground). The drain of the transfer transistor TR is electrically coupled to the floating diffusion FD and the gate of the transfer transistor TR is electrically coupled to the pixel drive line 23. The transfer transistor TR is, for example, a CMOS (Complementary Metal Oxide Semiconductor) transistor.

As described above, the floating diffusion FD shared by the four sensor pixels 12 is electrically coupled to the input end of the common readout circuit 22. The readout circuit 22 includes, for example, the reset transistor RST, the selection transistor SEL, and the amplification transistor AMP. It is to be noted that the selection transistor SEL may be omitted as necessary. The source of the reset transistor RST (the input end of the readout circuit 22) is electrically coupled to the floating diffusion FD and the drain of the reset transistor RST is electrically coupled to a power supply line VDD and the drain of the amplification transistor AMP. The gate of the reset transistor RST is electrically coupled to the pixel drive line 23. The source of the amplification transistor AMP is electrically coupled to the drain of the selection transistor SEL and the gate of the amplification transistor AMP is electrically coupled to the source of the reset transistor RST. The source of the selection transistor SEL (the output end of the readout circuit 22) is electrically coupled to the vertical signal line 24 and the gate of the selection transistor SEL is electrically coupled to the pixel drive line 23.

In a case where the transfer transistor TR is turned on, the transfer transistor TR transfers the electric charge of the photodiode PD to the floating diffusion FD. The gate of the transfer transistor TR (the transfer gate TG) includes, for example, a planar transfer gate TG as illustrated in FIG. 7 and is formed on the front surface of the semiconductor substrate 11. The reset transistor RST resets the electric potential of the floating diffusion FD to a predetermined electric potential. In a case where the reset transistor RST is turned on, the reset transistor RST resets the electric potential of the floating diffusion FD to the electric potential of the power supply line VDD. The selection transistor SEL controls the timing of outputting a pixel signal from the readout circuit 22. The amplification transistor AMP generates, as a pixel signal, a signal of a voltage corresponding to the level of electric charge held in the floating diffusion FD. The amplification transistor AMP is included in a source-follower type amplifier and outputs a pixel signal of a voltage corresponding to the level of electric charge generated in the photodiode PD. In a case where the selection transistor SEL is turned on, the amplification transistor AMP amplifies the electric potential of the floating diffusion FD and outputs a voltage corresponding to the electric potential to the column signal processing circuit 34 through the vertical signal line 24. The reset transistor RST, the amplification transistor AMP, and the selection transistor SEL are, for example, CMOS transistors.

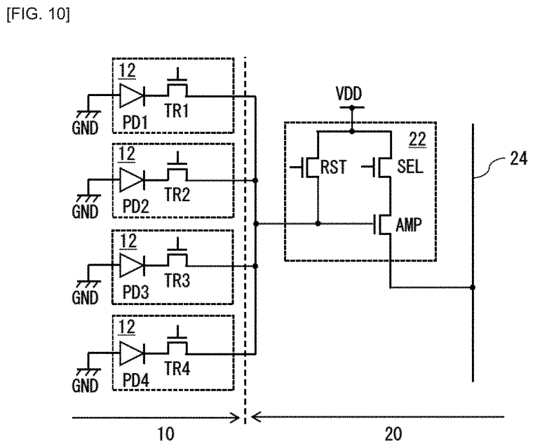

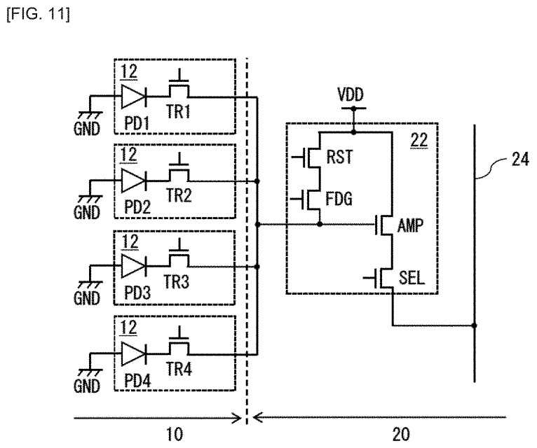

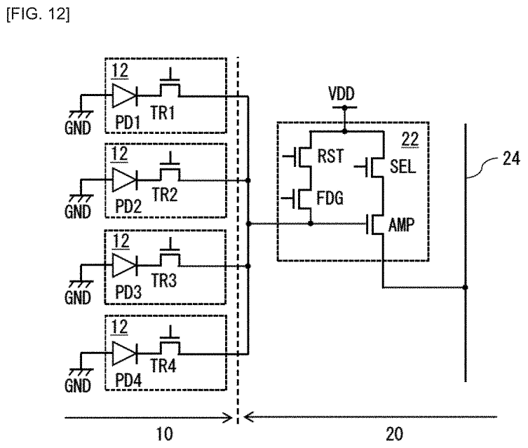

It is to be noted that, as illustrated in FIG. 10, the selection transistor SEL may be provided between the power supply line VDD and the amplification transistor AMP. In this case, the drain of the reset transistor RST is electrically coupled to the power supply line VDD and the drain of the selection transistor SEL. The source of the selection transistor SEL is electrically coupled to the drain of the amplification transistor AMP and the gate of the selection transistor SEL is electrically coupled to the pixel drive line 23. The source of the amplification transistor AMP (the output end of the readout circuit 22) is electrically coupled to the vertical signal line 24 and the gate of the amplification transistor AMP is electrically coupled to the source of the reset transistor RST. In addition, as illustrated in FIGS. 11 and 12, an FD transfer transistor FDG may be provided between the source of the reset transistor RST and the gate of the amplification transistor AMP.

The FD transfer transistor FDG is used to switch the conversion efficiency. In general, a pixel signal is small in shooting in a dark place. In a case where electric charge-voltage conversion is performed on the basis of Q=CV, the floating diffusion FD having larger capacitance (FD capacitance C) results in smaller V that is obtained in a case of conversion to a voltage by the amplification transistor AMP. Meanwhile, a bright place offers a large pixel signal. It is therefore not possible for the floating diffusion FD to receive the electric charge of the photodiode PD unless the FD capacitance C is large. Further, the FD capacitance C has to be large to prevent V from being too large (i.e., to make V small) in a case of conversion to a voltage by the amplification transistor AMP. Taking these into consideration, in a case where the FD transfer transistor FDG is turned on, the gate capacitance for the FD transfer transistor FDG is increased. This causes the whole FD capacitance C to be large. Meanwhile, in a case where the FD transfer transistor FDG is turned off, the whole FD capacitance C becomes small. In this way, switching the FD transfer transistor FDG on and off enables the FD capacitance C to be variable. This makes it possible to switch the conversion efficiency.

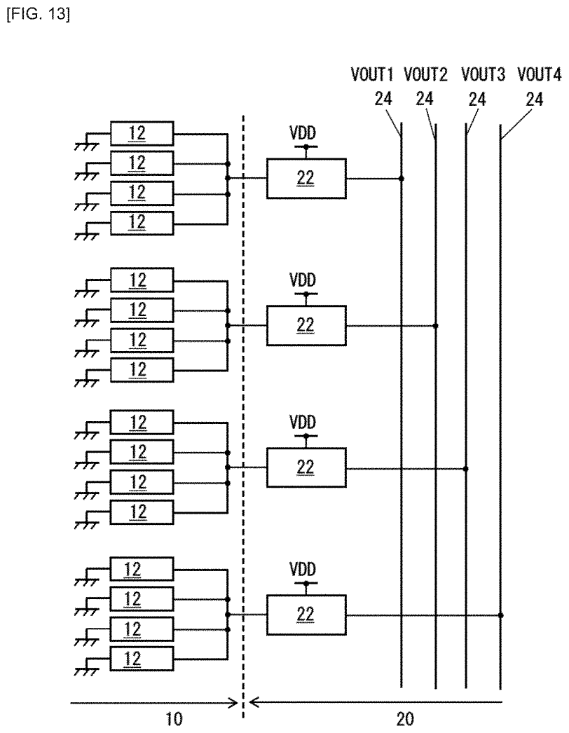

FIG. 13 illustrates an example of a coupling mode between the plurality of readout circuits 22 and the plurality of vertical signal lines 24. In a case where the plurality of readout circuits 22 is disposed side by side in the direction in which the vertical signal lines 24 extend (e.g., the column direction), the plurality of vertical signal lines 24 may be assigned one by one for the respective readout circuits 22. In a case where the four readout circuits 22 are disposed side by side in the direction in which the vertical signal lines 24 extend (e.g., the column direction), for example, as illustrated in FIG. 13, the four vertical signal lines 24 may be assigned one by one for the respective readout circuits 22. It is to be noted that an identification number (1, 2, 3, or 4) is assigned to the end of the symbol of each of the vertical signal lines 24 to distinguish the respective vertical signal lines 24 in FIG. 13.

Next, a cross-sectional configuration of the imaging unit 1A in the vertical direction is described with reference to FIG. 7. As described above, the imaging unit 1A has a configuration in which the first substrate 10, the second substrate 20, and the third substrate 30 are stacked in this order and further includes a color filter 40 and a light receiving lens 50 on the back surface (light incidence surface) side of the first substrate 10. The color filter 40 and the light receiving lens 50 are each provided one by one, for example, for each of the sensor pixels 12. In other words, the imaging unit 1A is a back-illuminated imaging unit.

As described above, the first substrate 10 includes an insulating layer 46 that is stacked on the front surface (a surface 11S1) of the semiconductor substrate 11. The first substrate 10 includes the insulating layer 46 as a portion of the interlayer insulating film 51. The insulating layer 46 is provided between the semiconductor substrate 11 and the semiconductor substrate 21 described below. The semiconductor substrate 11 includes a silicon substrate. The semiconductor substrate 11 includes, for example, the p well 42 in a portion of the front surface and near the front surface and includes the PD 41 of an electric conductivity type different from that of the p well 42 in another region (a region deeper than the p well 42). The p well 42 includes a p-type semiconductor region. The PD 41 includes a semiconductor region of an electric conductivity type (specifically, n-type) different from that of the p well 42. The semiconductor substrate 11 includes, in the p well 42, the floating diffusion FD as a semiconductor region of an electric conductivity type (specifically, n-type) different from that of the p well 42.

As described above, the first substrate 10 includes the photodiode PD and the transfer transistor TR for each of the sensor pixels 12 and shares the floating diffusion FD between the four sensor pixels 12. The first substrate 10 has a configuration in which the transfer transistor TR and the floating diffusion FD are provided on a portion of the semiconductor substrate 11 on the surface 11S1 side (the opposite side to the light incidence surface or the second substrate 20 side).

The first substrate 10 includes the element separation section 43 that separates the sensor pixels 12 from each other. As viewed from the normal direction (the direction vertical to the front surface of the semiconductor substrate 11) of the semiconductor substrate 11, the element separation section 43 does not completely surround the sensor pixel 12. The element separation section 43 has a gap (an unformed region) near the floating diffusion FD (the through wiring line 54) and near the through wiring line 47. The gap then allows the four sensor pixels 12 to share the one through wiring line 54 and allows the four sensor pixels 12A to share the one through wiring line 47. The element separation section 43 includes, for example, silicon oxide. The element separation section 43 penetrates, for example, the semiconductor substrate 11. The first substrate 10 further includes, for example, a p well layer 44 that is the side surface of the element separation section 43 and is in contact with the surface on the photodiode PD side. The p well layer 44 includes a semiconductor region of an electric conductivity type (specifically, p-type) different from that of the photodiode PD. The first substrate 10 further includes, for example, a fixed electric charge film 45 that is in contact with the back surface (a surface 11S2 or the other surface) of the semiconductor substrate 11. The fixed electric charge film 45 has negative fixed electric charge to suppress the generation of a dark current due to the interface state of the semiconductor substrate 11 on the light receiving surface side. The fixed electric charge film 45 is formed by using, for example, an insulating film having negative fixed electric charge. Examples of a material of such an insulating film include hafnium oxide, zircon oxide, aluminum oxide, titanium oxide, and tantalum oxide. An electric field induced by the fixed electric charge film 45 forms a hole accumulation layer at the interface of the semiconductor substrate 11 on the light receiving surface side. This hole accumulation layer suppresses the generation of electrons from the interface. The color filter 40 is provided on the back surface side of the semiconductor substrate 11. The color filter 40 is provided, for example, in contact with the fixed electric charge film 45 and is provided at a position opposed to the sensor pixel 12 with the fixed electric charge film 45 interposed in between. The light receiving lens 50 is provided, for example, in contact with the color filter 40 and is provided at a position opposed to the sensor pixel 12 with the color filter 40 and the fixed electric charge film 45 interposed in between.

As described above, the second substrate 20 includes an insulating layer 52 that is stacked on the semiconductor substrate 21. The second substrate 20 includes the insulating layer 52 as a portion of the interlayer insulating film 51. The insulating layer 52 is provided between the semiconductor substrate 21 and the semiconductor substrate 31. The semiconductor substrate 21 includes a silicon substrate. The second substrate 20 includes the one readout circuit 22 for every four sensor pixels 12. The second substrate 20 has a configuration in which the readout circuit 22 is provided on a portion of the semiconductor substrate 21 on the front surface (the surface 21S1 opposed to the third substrate 30 or one surface) side. The second substrate 20 is bonded to the first substrate 10 with the back surface (a surface 21S2 or the other surface) of the semiconductor substrate 21 opposed to the front surface (the surface 11S1) of the semiconductor substrate 11. In other words, the second substrate 20 is bonded to the first substrate 10 in a face-to-back manner. The second substrate 20 further includes the insulating layer 53 in the same layer as the semiconductor substrate 21. The second substrate 20 includes the insulating layer 53 as a portion of the interlayer insulating film 51. The insulating layer 53 is formed in the opening 21H that extends through the semiconductor substrate 21. The insulating layer 53 is provided to cover the side surfaces of the through wiring lines 47, 48, and 54 described above.

The second substrate 20 includes, for example, the plurality of coupling sections 59 in the insulating layer 52. The plurality of coupling sections 59 is electrically coupled to the readout circuit 22 and the semiconductor substrate 21. The second substrate 20 further includes, for example, a wiring layer 56 on the insulating layer 52. The wiring layer 56 includes, for example, an insulating layer 57 and the plurality of pixel drive lines 23 and the plurality of vertical signal lines 24. The plurality of pixel drive lines 23 and the plurality of vertical signal lines 24 are provided in the insulating layer 57. The wiring layer 56 further includes, for example, the plurality of coupling wiring lines 55 in the insulating layer 57. The one coupling wiring line 55 is provided for every four sensor pixels 12. The coupling wiring line 55 electrically couples the respective through wiring lines 54 to each other. The through wiring lines 54 are electrically coupled to the floating diffusions FD included in the four sensor pixels 12 that share the readout circuit 22.

The wiring layer 56 further includes, for example, a plurality of pad electrodes 58 in the insulating layer 57. Each of the pad electrodes 58 is formed by using, for example, a metal such as Cu (copper) and Al (aluminum). Each of the pad electrodes 58 is exposed from the surface of the wiring layer 56. Each of the pad electrodes 58 is used to electrically couple the second substrate 20 and the third substrate 30 and bond the second substrate 20 and the third substrate 30 together. The plurality of pad electrodes 58 is provided one by one, for example, for the respective pixel drive lines 23 and the respective vertical signal lines 24. Here, the total number of pad electrodes 58 (or the total number of junctions between the pad electrode 58 and a pad electrode 64 (described below) is smaller than the total number of sensor pixels 12 included in the first substrate 10.

The third substrate 30 includes, for example, an interlayer insulating film 61 that is stacked on the semiconductor substrate 31. It is to be noted that, as described below, the third substrate 30 is bonded to the second substrate 20 on the front surfaces. Therefore, in a case where the components in the third substrate 30 are described, the vertical relationship to be described is opposite to the vertical direction in the diagram. The semiconductor substrate 31 includes a silicon substrate. The third substrate 30 has a configuration in which the logic circuit 32 is provided on a portion of the semiconductor substrate 31 on the front surface (a surface 31S1) side. The third substrate 30 further includes, for example, a wiring layer 62 on the interlayer insulating film 61. The wiring layer 62 includes, for example, an insulating layer 63 and the plurality of pad electrodes 64 that is provided in the insulating layer 63. The plurality of pad electrodes 64 is electrically coupled to the logic circuit 32. Each of the pad electrodes 64 is formed by using, for example, Cu (copper). Each of the pad electrodes 64 is exposed from the surface of the wiring layer 62. Each of the pad electrodes 64 is used to electrically couple the second substrate 20 and the third substrate 30 and bond the second substrate 20 and the third substrate 30 together. In addition, the pad electrode 64 does not necessarily have to be a plurality of pad electrodes. Even one pad electrode is able to be electrically coupled to the logic circuit 32. The second substrate 20 and the third substrate 30 are electrically coupled to each other by bonding the pad electrodes 58 and 64 to each other. In other words, the transfer gate TG of the transfer transistor TR is electrically coupled to the logic circuit 32 through the through wiring line 48 and the pad electrodes 58 and 64. The third substrate 30 is bonded to the second substrate 20 with the front surface (the surface 31S1) of the semiconductor substrate 31 opposed to the front surface (the surface 21S1) of the semiconductor substrate 21. In other words, the third substrate 30 is bonded to the second substrate 20 in a face-to-face manner.

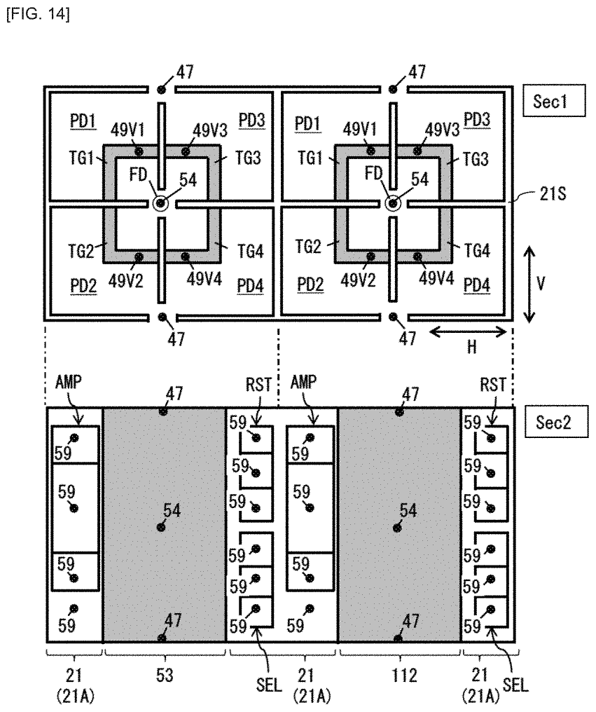

FIG. 14 illustrates an example of a cross-sectional configuration of the imaging unit 1A in the horizontal direction. The diagram on the upper side of FIG. 14 is a diagram illustrating an example of a cross-sectional configuration taken along a cross section Sec1 in FIG. 7 and the diagram on the lower side of FIG. 14 is a diagram illustrating an example of a cross-sectional configuration taken along a cross section Sec2 in FIG. 1. FIG. 14 exemplifies a configuration in which two sets of 2×2 or four sensor pixels 12 are arranged in a second direction H. It is to be noted that a diagram illustrating an example of the front surface configuration of the semiconductor substrate 11 is superimposed on a diagram illustrating the example of the cross-sectional configuration taken along the cross section Sec1 in FIG. 7 and the insulating layer 46 is omitted in the cross-sectional view on the upper side of FIG. 14. In addition, a diagram illustrating an example of the front surface configuration of the semiconductor substrate 21 is superimposed on a diagram illustrating the example of the cross-sectional configuration taken along the cross section Sec2 in FIG. 7 in the cross-sectional view on the lower side of FIG. 14.

In the plurality of sensor pixels 12 disposed in a matrix, the four sensor pixels 12 corresponding to a region obtained by shifting the unit region corresponding to the four sensor pixels 12 that share the one floating diffusion FD by the one sensor pixel 12 in the first direction V is referred to as four sensor pixels 12A for the sake of convenience. In this case, the first substrate 10 shares the through wiring line 47 between the four sensor pixels 12A. The first direction V is parallel with one (e.g., the column direction) of two arrangement directions (e.g., the row direction and the column direction) of the plurality of sensor pixels 12 disposed in a matrix. In the four sensor pixels 12 that share the floating diffusion FD and the readout circuit 22, the four transfer gates TG are disposed to surround the one floating diffusion FD and the four transfer gates TG form, for example, an annular shape.

The insulating layer 53 includes a plurality of blocks extending in the first direction V. The semiconductor substrate 21 extends in the first direction V and includes the plurality of island-shaped blocks 21A disposed side by side in the second direction H orthogonal to the first direction V with the insulating layer 53 interposed in between. Each of the blocks 21A is provided, for example, with a plurality of sets of reset transistors RST, amplification transistors AMP, and selection transistors SEL. The one readout circuit 22 shared by the four sensor pixels 12 includes, for example, the reset transistor RST, the amplification transistor AMP, and the selection transistor SEL in a region opposed to the four sensor pixels 12. The one readout circuit 22 shared by the four sensor pixels 12 includes, for example, the amplification transistor AMP in the left adjacent block 21A of the insulating layer 53 and the reset transistor RST and the selection transistor SEL in the right adjacent block 21A of the insulating layer 53.

FIG. 15 illustrates another example of a cross-sectional configuration of the imaging unit 1A in the horizontal direction. The first substrate 10 includes the photodiode PD and the transfer transistor TR for each of the sensor pixels 12 and shares the floating diffusion FD between the four sensor pixels 12. Further, the first substrate 10 includes the element separation section 43 that separates the photodiode PD and the transfer transistor TR for each of the sensor pixels 12. FIG. 15 is different from the cross section Sec2 in FIG. 14 described above in that the semiconductor substrate 21 provided with the reset transistor RST, the amplification transistor AMP, and the selection transistor SEL has an island shape for every four sensor pixels that share the one floating diffusion FD.

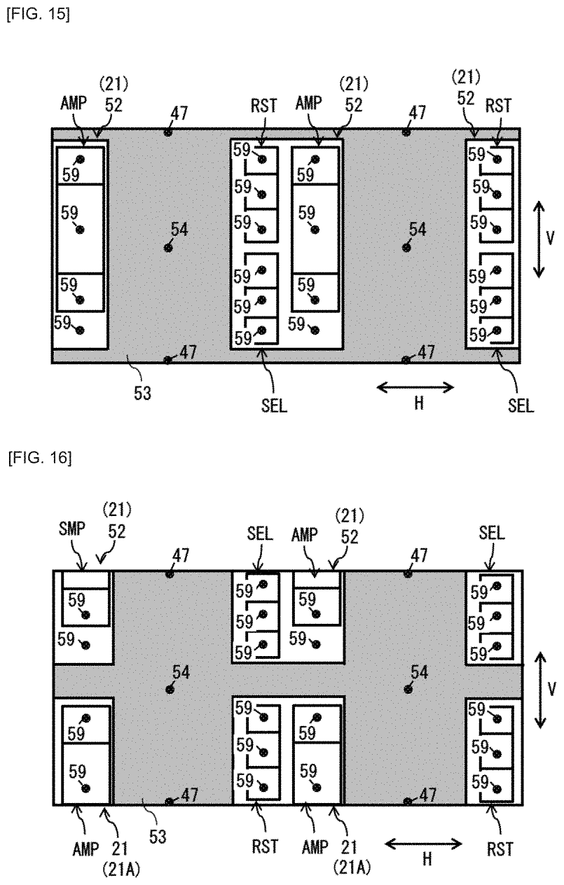

FIG. 16 illustrates another example of a cross-sectional configuration of the imaging unit 1A in the horizontal direction. The first substrate 10 includes the photodiode PD and the transfer transistor TR for each of the sensor pixels 12 and shares the floating diffusion FD between the four sensor pixels 12. Further, the first substrate 10 includes the element separation section 43 that separates the photodiode PD and the transfer transistor TR for each of the sensor pixels 12. FIG. 16 illustrates that the semiconductor substrates 21 are disposed to be shifted in a first direction V by one sensor pixel. Each of the semiconductor substrates 21 has an island shape for every four sensor pixels that share the one floating diffusion FD in FIG. 15.

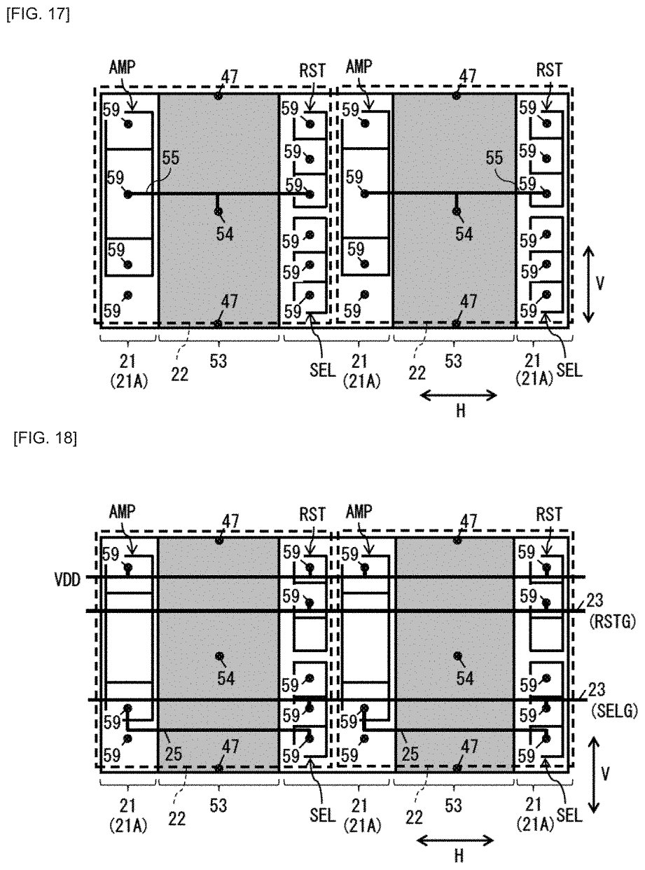

Each of FIGS. 17, 18, 19 and 20 illustrates an example of a wiring line layout of the imaging unit 1A within the horizontal plane. Each of FIGS. 17 to 20 exemplifies a case where the one readout circuit 22 shared by the four sensor pixels 12 is provided in a region opposed to the four sensor pixels 12. The wiring lines illustrated in FIGS. 17 to 20 are provided, for example, in layers different from each other in the wiring layer 56.

The through wiring line 54 is electrically coupled to the coupling wiring line 55, for example, as illustrated in FIG. 17. The through wiring line 54 is further electrically coupled to the gate of the amplification transistor AMP included in the left adjacent block 21A of the insulating layer 53 and the gate of the reset transistor RST included in the right adjacent block 21A of the insulating layer 53 through the coupling wiring line 55 and the coupling section 59, for example, as illustrated in FIG. 17.

The power supply line VDD is disposed at positions opposed to the readout circuits 22 disposed side by side in the second direction H, for example, as illustrated in FIG. 18. The power supply line VDD is electrically coupled to the drain of the amplification transistor AMP and the drain of the reset transistor RST of each of the readout circuits 22 disposed side by side in the second direction H through the coupling section 59, for example, as illustrated in FIG. 18. Each of the two pixel drive lines 23 is disposed at positions opposed to the readout circuits 22 disposed side by side in the second direction H, for example, as illustrated in FIG. 18. One (a second control line) of the pixel drive lines 23 is a wiring line RSTG electrically coupled to the gate of the reset transistor RST of each of the readout circuits 22 disposed side by side in the second direction H, for example, as illustrated in FIG. 18. The other (a third control line) of the pixel drive lines 23 is a wiring line SELG electrically coupled to the gate of the selection transistor SEL of each of the readout circuits 22 disposed side by side in the second direction H, for example, as illustrated in FIG. 18. In each of the readout circuits 22, the source of the amplification transistor AMP and the drain of the selection transistor SEL are electrically coupled to each other through a wiring line 25, for example, as illustrated in FIG. 18.

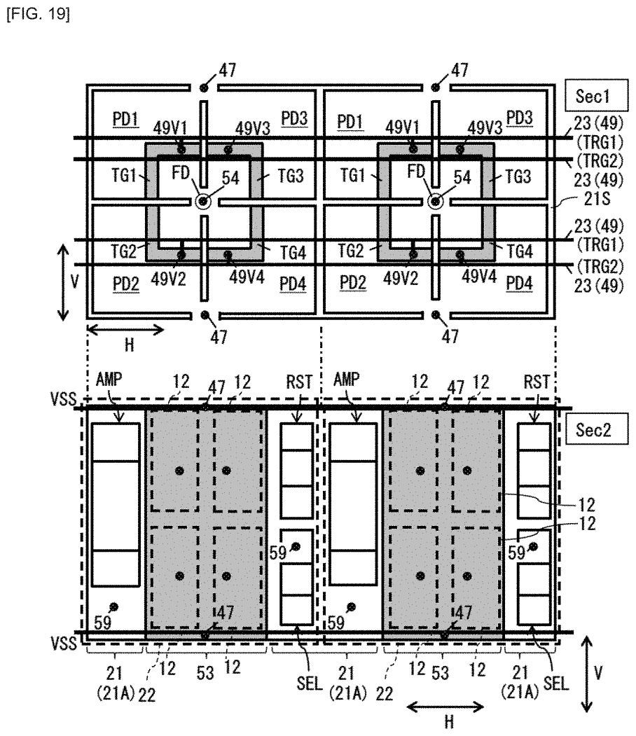

Each of the two power supply lines VSS is disposed at positions opposed to the readout circuits 22 disposed side by side in the second direction H, for example, as illustrated in the cross section Sec2 of FIG. 19. Each of the power supply lines VSS is electrically coupled to the plurality of through wiring lines 47 at positions opposed to the respective sensor pixels 12 disposed side by side in the second direction H, for example, as illustrated in the cross section Sec2 of FIG. 19. Each of the four pixel drive lines 23 (the wiring lines 49) is disposed at positions opposed to the readout circuits 22 disposed side by side in the second direction H, for example, as illustrated in the cross section Sec1 of FIG. 19. Each of the four pixel drive lines 23 (the wiring lines 49) is a wiring line TRG electrically coupled to the through wiring line 48 of the one sensor pixel 12 of the four sensor pixels 12 corresponding to each of the readout circuits 22 disposed side by side in the second direction H, for example. In other words, the four pixel drive lines 23 (the wiring lines 49 or first control lines) are each electrically coupled to the gate (transfer gate TG) of the transfer transistor TR of each of the sensor pixels 12 disposed side by side in the second direction H. In the cross section Sec1 of FIG. 19, to distinguish the wiring lines TRG from each other, an identifier (1, 2, 3, or 4) is assigned to the end of each of the wiring lines TRG.

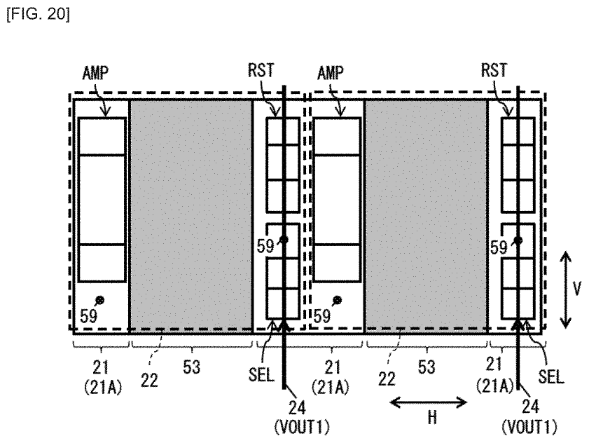

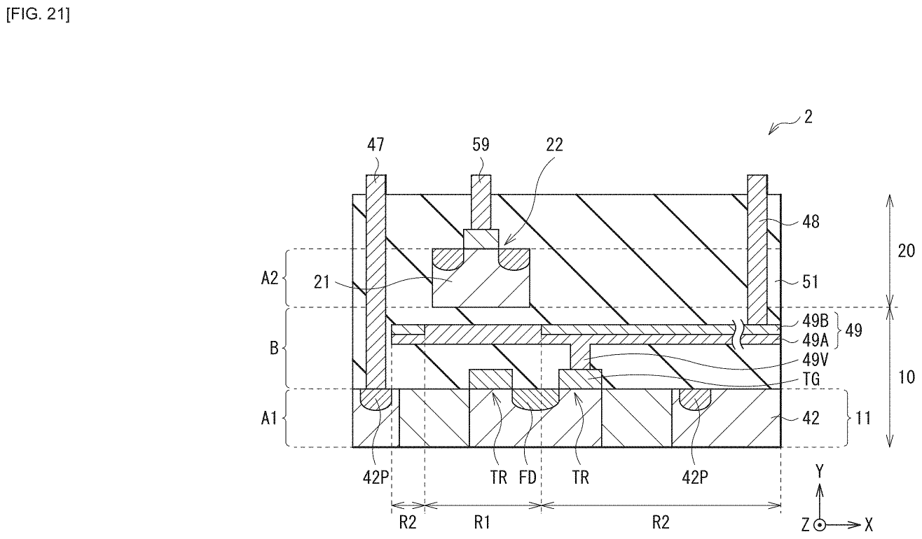

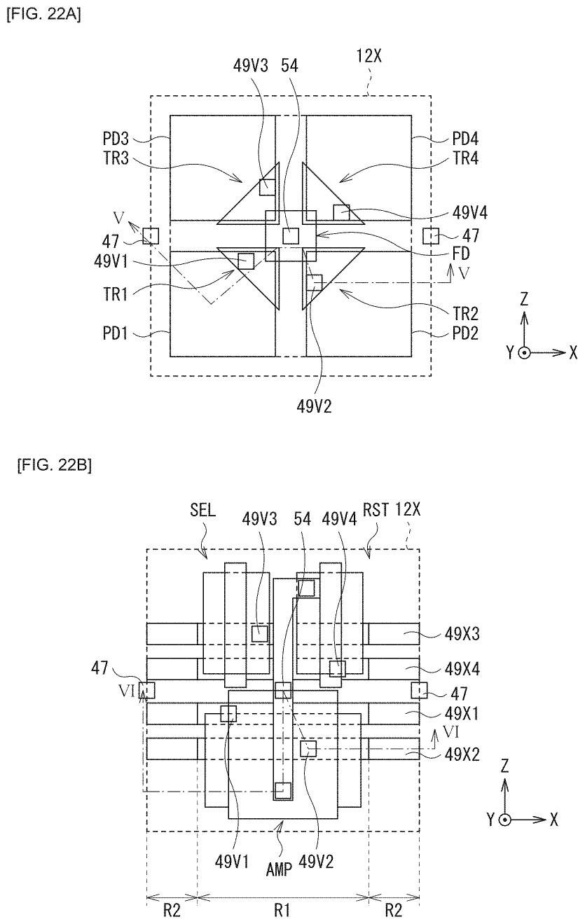

The vertical signal line 24 is disposed at positions opposed to the readout circuits 22 disposed side by side in the first direction V, for example, as illustrated in FIG. 20. The vertical signal line 24 (an output line) is electrically coupled to the output end (the source of the amplification transistor AMP) of each of the readout circuits 22 disposed side by side in the first direction V, for example, as illustrated in FIG. 20.

It is possible to manufacture the imaging unit 1A according to the present embodiment as follows after the steps of manufacturing the semiconductor device 1 described, for example, with reference to FIGS. 4A to 4I.

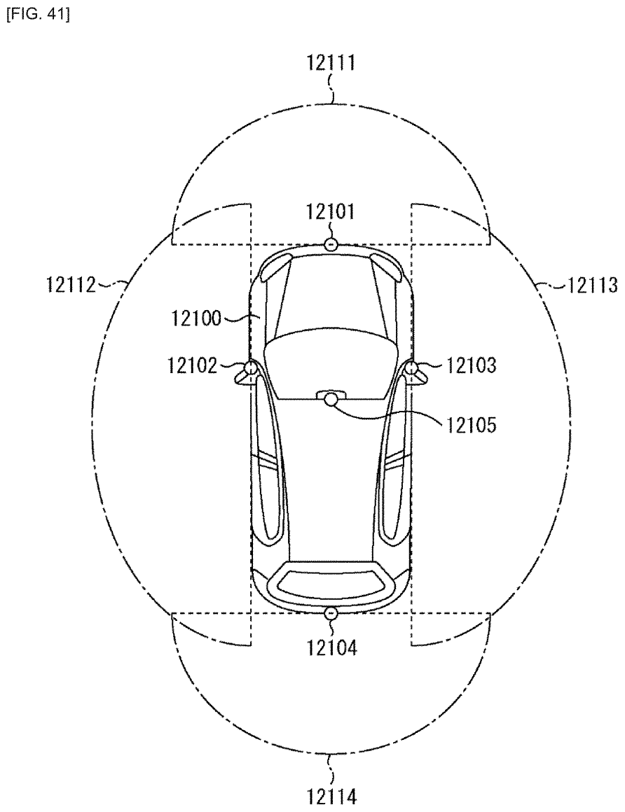

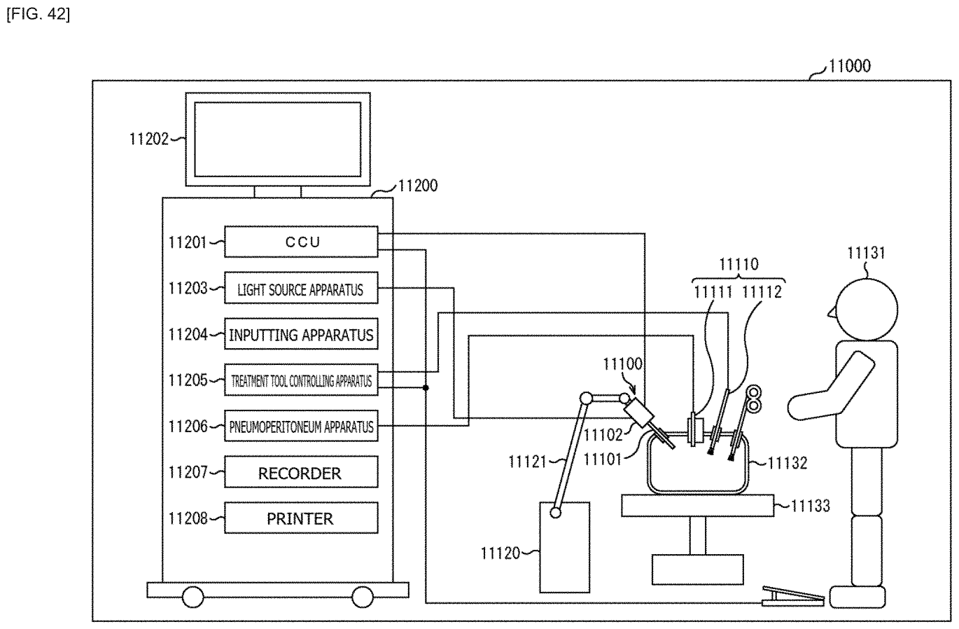

For example, after the second substrate 20 is formed as illustrated in FIG. 41, the second substrate 20 is bonded to the third substrate 30 with the front surface of the semiconductor substrate 21 opposed to the front surface side of the semiconductor substrate 31. The logic circuit 32 and the wiring layer 62 are formed on the third substrate 30. In this case, the pad electrode 58 of the second substrate 20 and the pad electrode 64 of the third substrate 30 are bonded to each other, thereby electrically coupling the second substrate 20 and the third substrate 30 to each other. In this way, the imaging unit 1A illustrated in FIG. 7 is manufactured.

### 1-4. Workings and Effects

The introduction of a miniaturization process and improvement in packaging density have allowed an imaging unit having a two-dimensional structure to have smaller area per pixel in the past. In recent years, an imaging unit having a three-dimensional structure has been developed to allow the imaging unit to have a still smaller size and allow one pixel to have smaller area. In the imaging unit having the three-dimensional structure, for example, a semiconductor substrate including a plurality of sensor pixels and a semiconductor substrate including a signal processing circuit are stacked. The signal processing circuit processes a signal obtained at each of the sensor pixels. This allows sensor pixels to have a higher degree of integration and a signal processing circuit to have a larger size, while maintaining a chip size equivalent to an existing chip size.

Incidentally, in the imaging unit having a three-dimensional structure, a conventional MOS process is used to form an upper layer device in which a readout circuit or the like is formed. The conventional MOS process has a high temperature process that entails 1000° C. or more. Wiring is therefore performed after the upper layer device is formed. The imaging unit having a three-dimensional structure therefore tends to have a wiring line redundantly drawn. For example, as with the semiconductor device 100 (FIG. 5) described above, the plurality of through wiring lines 1048 is provided around the through wiring line 1054 to extend in parallel. The capacitance (parasitic capacitance) increases between the through wiring line 1054 and the through wiring lines 1048. The through wiring line 1054 extends in the normal direction of a semiconductor substrate 1011. The plurality of through wiring lines 1048 electrically couples the transfer gate TG of the transfer transistor TR and a pixel drive line (not illustrated) provided to the second substrate (the device layer A200). In this way, the imaging unit having a three-dimensional structure tends to have parasitic capacitance that is increased by fringing or the like.

Meanwhile, in a case where the upper layer device is formed in a low temperature process that entails, for example, 400° C. or less, it is possible to draw a wiring line under the upper layer device. This makes it possible to minimize the parasitic capacitance, but decreases the quality of the upper layer device. Specifically, the noise characteristics or the like of the readout circuit deteriorate.

In contrast, in the present embodiment, the wiring line 49 is formed in the insulating layer 46 between the semiconductor substrate 11 included in the first substrate 10 and the semiconductor substrate 21 included in the second substrate 20. The wiring line 49 extends in the direction parallel with the semiconductor substrate 11. The semiconductor layer 49A and the metal layer 49B are stacked in the wiring line 49. This decreases the distance of through wiring lines extending in parallel in the stack direction of the first substrate 10 and the second substrate 20. Specifically, for example, the distance of the through wiring line 1054 illustrated in FIG. 5 and the through wiring line 1048 extending in parallel is decreased to the distance corresponding to the via 49V as illustrated in FIG. 1. The through wiring line 1054 electrically couples the floating diffusion FD and the readout circuit 1022. The through wiring line 1048 electrically couples the gate (TG) of the transfer transistor TR and the vertical drive circuit 33. The via 49V couples the gate (TG) of the transfer transistor TR and the wiring line 49. In addition, the total number of through wiring lines extending in the stack direction of the first substrate 10 and the second substrate 20 decreases.

As described above, it is possible to reduce the parasitic capacitance in the imaging unit 1A having a three-dimensional structure in which the first substrate 10, the second substrate 20, and the third substrate 30 are stacked. The first substrate 10 includes the sensor pixel 12 that performs photoelectric conversion. The second substrate 20 includes the readout circuit 22 that outputs an image signal based on electric charge outputted from the sensor pixel 12. The third substrate 30 includes the logic circuit 32.

In addition, in the present embodiment, the wiring line 49 has a stacked structure of the semiconductor layer 49A and the metal layer 49B. This makes it possible to reduce the resistance of the wiring line 49 as compared with a case where the semiconductor layer 49A alone is included. In other words, it is possible to form a wiring line having low resistance between the semiconductor substrate 11 included in the first substrate 10 and the semiconductor substrate 21 included in the second substrate 20.

The following describes second to fifth embodiments and modification examples 1 to 10. It is to be noted that the following description denotes the same components as those of the first embodiment described above with the same symbols and the descriptions thereof are omitted as appropriate.

### 2. Second Embodiment

FIG. 21 schematically illustrates a cross-sectional configuration of a semiconductor device (a semiconductor device 2) according to the second embodiment of the present disclosure in the vertical direction. FIG. 22A illustrates a layout in the device layer A1 and FIG. 22B illustrates a layout in the device layer A2 and the wiring layer B. It is to be noted that the cross section illustrated in FIG. 21 corresponds to a V-V line and a VI-VI line illustrated in FIGS. 22A and 22B. The semiconductor device 2 is a stacked body in which the first substrate 10 and the second substrate 20 are stacked as in the first embodiment described above. The first substrate 10 includes the sensor pixel 12 in the device layer A1 (the semiconductor substrate 11). The sensor pixel 12 performs photoelectric conversion. The second substrate 20 includes the readout circuit 22 in the device layer A2 (the semiconductor substrate 21). The readout circuit 22 outputs an image signal based on electric charge outputted from the sensor pixel 12.

In the first embodiment described above, the example has been described in which the reset transistor RST and the selection transistor SEL are disposed on a side of the unit region 12X, the amplification transistor AMP is disposed on the opposite side, and the wiring line 49 is formed in between. The reset transistor RST, the selection transistor SEL, and the amplification transistor AMP may be, however, disposed at protrusions in the middle of the unit region 12X as illustrated in FIG. 22B. In this case, as illustrated in FIG. 21, each of the four wiring lines 49X1, 49X2, 49X3, and 49X4 disposed in a strip shape in the unit region 12X has a single layer structure of the semiconductor layer 49A in a region R1 and has a stacked structure of the semiconductor layer 49A and the metal layer 49B in a region R2 as in the first embodiment described above. The semiconductor substrate 21 is located above the region R1. The semiconductor substrate 21 is not located above the region R2. This region R2 above which the semiconductor substrate 21 is not located corresponds to a “stack region” according to the present disclosure.

As described above, even in a case where the reset transistor RST, the selection transistor SEL, and the amplification transistor AMP are disposed above the wiring line 49, providing the region R2 with a stack region R of the semiconductor layer 49A and the metal layer 49B offers an effect similar to that of the first embodiment described above. The reset transistor RST, the selection transistor SEL, or the amplification transistor AMP is not disposed in the region R2.

### 3. Third Embodiment

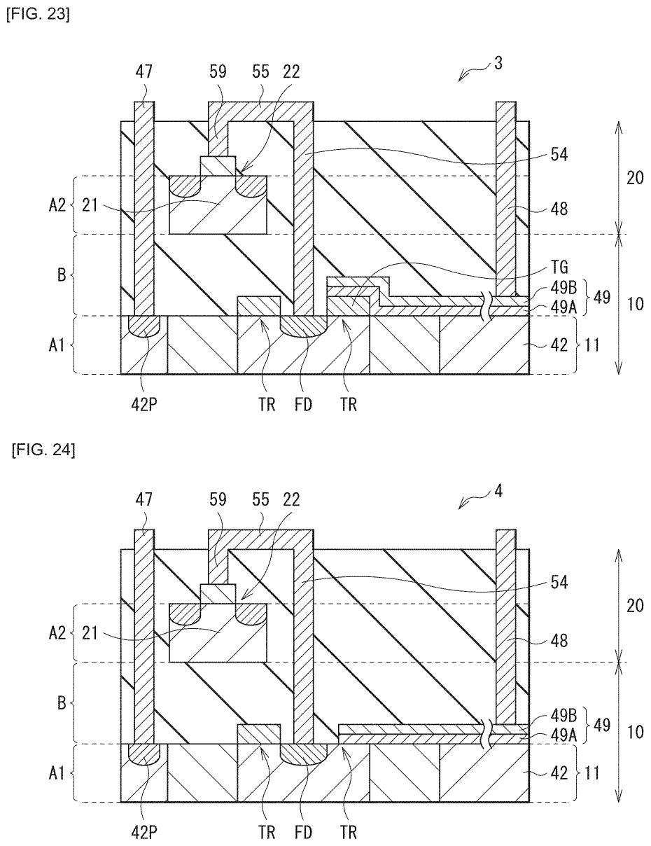

FIG. 23 schematically illustrates a cross-sectional configuration of a semiconductor device (a semiconductor device 3) according to the third embodiment of the present disclosure in the vertical direction. The semiconductor device 3 is a stacked body in which the first substrate 10 and the second substrate 20 are stacked as in the first embodiment described above. The first substrate 10 includes the sensor pixel 12 in the device layer A1 (the semiconductor substrate 11). The sensor pixel 12 performs photoelectric conversion. The second substrate 20 includes the readout circuit 22 in the device layer A2 (the semiconductor substrate 21). The readout circuit 22 outputs an image signal based on electric charge outputted from the sensor pixel 12. In the semiconductor device 3 according to the present embodiment, the wiring line 49 is directly formed on the transfer gate TG of the transfer transistor TR without using the via 49V.

Even in a case where the wiring line 49 is directly formed on the transfer gate TG of the transfer transistor TR without using the via 49V in this way, an effect similar to that of the first embodiment described above is obtained.

### 4. Fourth Embodiment

FIG. 24 schematically illustrates a cross-sectional configuration of the main portion of a semiconductor device (a semiconductor device 4) according to the fourth embodiment of the present disclosure in the vertical direction. The semiconductor device 4 is a stacked body in which the first substrate 10 and the second substrate 20 are stacked as in the first embodiment described above. The first substrate 10 includes the sensor pixel 12 in the device layer A1 (the semiconductor substrate 11). The sensor pixel 12 performs photoelectric conversion. The second substrate 20 includes the readout circuit 22 in the device layer A2 (the semiconductor substrate 21). The readout circuit 22 outputs an image signal based on electric charge outputted from the sensor pixel 12. The imaging unit 1A according to the present embodiment uses the transfer gate TG of the transfer transistor TR as the wiring line 49.

Even in a case where the wiring line 49 is formed by using the transfer gate TG of the transfer transistor TR in this way, an effect similar to that of the first embodiment described above is obtained. It is to be noted that the transfer gate TG also serving as this wiring line 49 is formed (the semiconductor layer 49A) by using a semiconductor material such as polysilicon. In a case where the semiconductor substrate 21 is not located above the transfer gate TG, the transfer gate TG has a stacked structure in which the semiconductor layer 49A and the metal layer 49B are stacked as illustrated in FIG. 24.

### 5. Fifth Embodiment

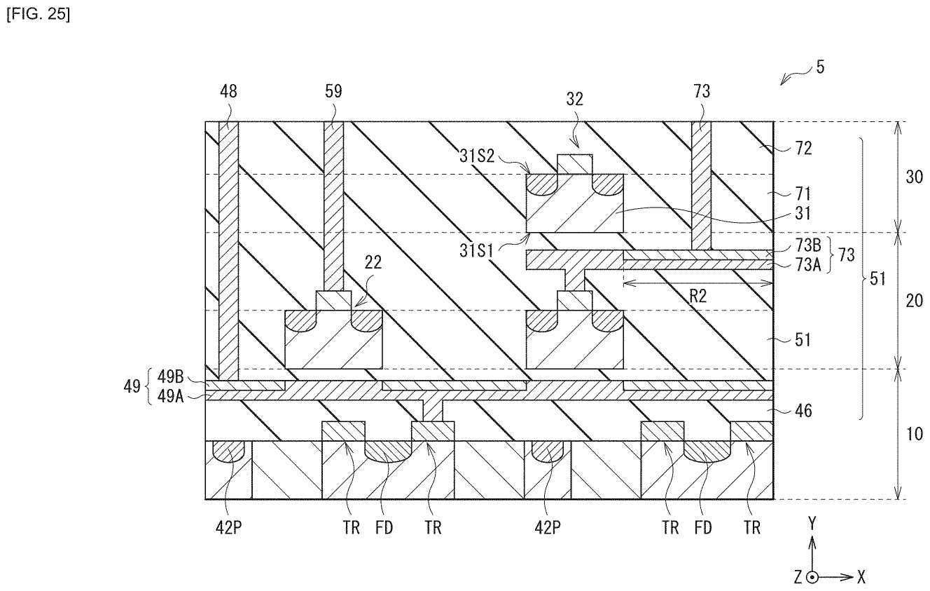

FIG. 25 schematically illustrates a cross-sectional configuration of the main portion of a semiconductor device (a semiconductor device 5) according to the fifth embodiment of the present disclosure in the vertical direction. The semiconductor device 5 is an imaging unit having a three-dimensional structure in which the first substrate 10, the second substrate 20, and the third substrate 30 are stacked as with the imaging unit 1A according to the first embodiment described above. The first substrate 10 includes the sensor pixel 12 on the semiconductor substrate 11. The sensor pixel 12 performs photoelectric conversion. The second substrate 20 includes the readout circuit 22 on the semiconductor substrate 21. The readout circuit 22 outputs an image signal based on electric charge outputted from the sensor pixel 12. The third substrate 30 includes the logic circuit 32. In the semiconductor device 5 according to the present embodiment, a wiring line 73 is formed between the semiconductor substrate 21 included in the second substrate 20 and the semiconductor substrate 31 included in the third substrate 30. The wiring line 73 extends between the semiconductor substrate 21 and the semiconductor substrate 31. The wiring line 73 has the region R2 in a portion of which a semiconductor layer 72A and a metal layer 72B are stacked.

The semiconductor device 5 includes the semiconductor substrate 31, an insulating layer 71, and an insulating layer 72 on the second substrate 20 as the third substrate 30. The insulating layer 71 is provided in the same layer as the semiconductor substrate 31. The insulating layer 71 serves as a portion of the interlayer insulating film 51. The insulating layer 72 is provided on the semiconductor substrate 31 and the insulating layer 71. The insulating layer 72 serves an as a portion of the interlayer insulating film 51. The semiconductor substrate 31 is provided, for example, with the logic circuit 32 on a surface S2. The insulating layer 52 is provided with the wiring line 73 as described above. The wiring line 73 has a stacked structure in which a metal layer 73B is stacked on a semiconductor layer 73A in the region R2. The semiconductor substrate 31 is not located above the region R2.

In this way, providing the wiring line 73 in the interlayer insulating film 51 (specifically, the insulating layer 52) between the semiconductor substrate 21 and the semiconductor substrate 31 increases the freedom of drawing a wiring line in the semiconductor device 5 having a three-dimensional structure in which the first substrate 10, the second substrate 20, and the third substrate 30 are stacked. This makes it possible to further decrease the number of through wiring lines extending in parallel with each other. The semiconductor layer 73A and the metal layer 73B are stacked in the wiring line 73. This makes it possible to further reduce the parasitic capacitance between the through wiring lines.

It is to be noted that the amplification transistor AMP, the reset transistor RST, and the selection transistor SEL that may be included in the readout circuit 22 are formed on the same semiconductor substrate 21 of the second substrate 20 according to any of the first to fifth embodiments described above. However, for example, on the second substrate 20 according to any of the first to fifth embodiments described above, at least one transistor included in the readout circuit 22 may be formed on the semiconductor substrate 21 and the remaining transistors may be formed on a semiconductor substrate (e.g., a semiconductor substrate 21X) different from the semiconductor substrate 11 and the semiconductor substrate 21. Although not illustrated, the second substrate 20 may be then formed, for example, by forming the insulating layers 52 and 57, the coupling section 59, and the coupling wiring line 55 on the semiconductor substrate 21 and further stacking the semiconductor substrate 21X. The semiconductor substrate 21X is stacked in the region opposite to the semiconductor substrate 11 side in the positional relationship with the interlayer insulating film 51. It is possible to form a desired transistor. As an example, it is possible to form the amplification transistor AMP on the semiconductor substrate 21 and form the reset transistor RST and/or the selection transistor SEL on the semiconductor substrate 21X.

In addition, the second substrate 20 according to any of the first to fifth embodiments described above may be provided with a plurality of new semiconductor substrates and each of the new semiconductor substrates may be provided with a desired transistor included in the readout circuit 22. As an example, it is possible to form the amplification transistor AMP on the semiconductor substrate 21. Further, it is possible to stack an insulating layer, a coupling section, and a coupling wiring line on the semiconductor substrate 21, stack the semiconductor substrate 21X thereon, and form the reset transistor RST on the semiconductor substrate 21X. It is possible to stack an insulating layer, a coupling section, and a coupling wiring line on the semiconductor substrate 21X, stack a semiconductor substrate 21Y thereon, and form the selection transistor SEL on the semiconductor substrate 21Y. The transistor formed on each of the semiconductor substrates 21, 21X, and 21Y may be any of the transistors included in the readout circuit 22.

In this way, providing the second substrate 20 with a plurality of semiconductor substrates makes it possible to decrease the area of the semiconductor substrate 21 occupied by the one readout circuit 22. In a case where it is possible to decrease the area of each of the readout circuits 22 or make each of transistors finer, it is possible to decrease even the area of the chip. In addition, it is possible to increase the area of a desired transistor of the amplification transistor AMP, the reset transistor RST, and the selection transistor SEL that may be included in the readout circuit 22. Especially increasing the area of the amplification transistor AMP makes an effect of reducing noise expectable.

### 6. Modification Examples

### 6-1. Modification Example 1

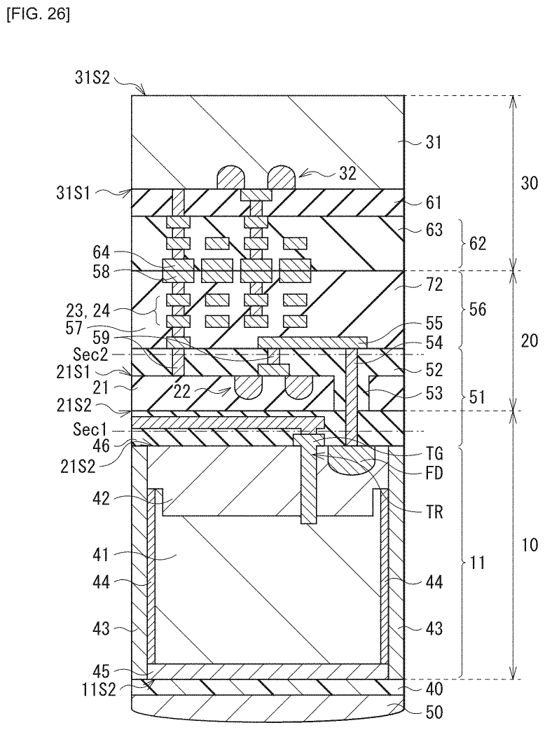

FIG. 26 illustrates an example of a cross-sectional configuration of an imaging unit (e.g., the imaging unit 1A) according to a modification example (a modification example 1) of the first to fifth embodiments described above in the vertical direction. In the present modification example, the transfer transistor TR includes a vertical transfer gate TG. The vertical transfer gate TG extends to penetrate the p well 42 from the surface of the semiconductor substrate 11 to such a depth as to reach PD 41 as illustrated in FIG. 26. Even in a case where the vertical transfer gate TG is used for the transfer transistor TR, the imaging unit 1A has effects similar to those of the first embodiment described above.

### 6-2. Modification Example 2

FIG. 27 illustrates an example of a cross-sectional configuration of an imaging unit (e.g., the imaging unit 1A) according to a modification example (a modification example 2) of the first to fifth embodiments described above in the vertical direction. In the present modification example, the second substrate 20 and the third substrate 30 are electrically coupled in a region opposed to the peripheral region 14 on the first substrate 10. The peripheral region 14 corresponds to a frame region of the first substrate 10 and is provided on the periphery of the pixel region 13. In the present modification example, the second substrate 20 includes the plurality of pad electrodes 58 in the region opposed to the peripheral region 14 and the third substrate 30 includes the plurality of pad electrodes 64 in the region opposed to the peripheral region 14. The second substrate 20 and the third substrate 30 are electrically coupled to each other by bonding the pad electrodes 58 and 64 to each other. The pad electrodes 58 and 64 are provided in the region opposed to the peripheral region 14.

The second substrate 20 and the third substrate 30 are electrically coupled to each other by bonding the pad electrodes 58 and 64 to each other in this way in the present modification example. The pad electrodes 58 and 64 are provided in the region opposed to the peripheral region 14. This makes it possible to reduce the possibility of preventing one pixel from having smaller area as compared with a case where the pad electrodes 58 and 64 are bonded to each other in a region opposed to the pixel region 13. Thus, in addition to the effects of the first embodiment described above, it is possible to provide the imaging unit 1A having a three-layer structure that does not prevent one pixel from having smaller area while maintaining a chip size equivalent to an existing chip size.

### 6-3. Modification Example 3

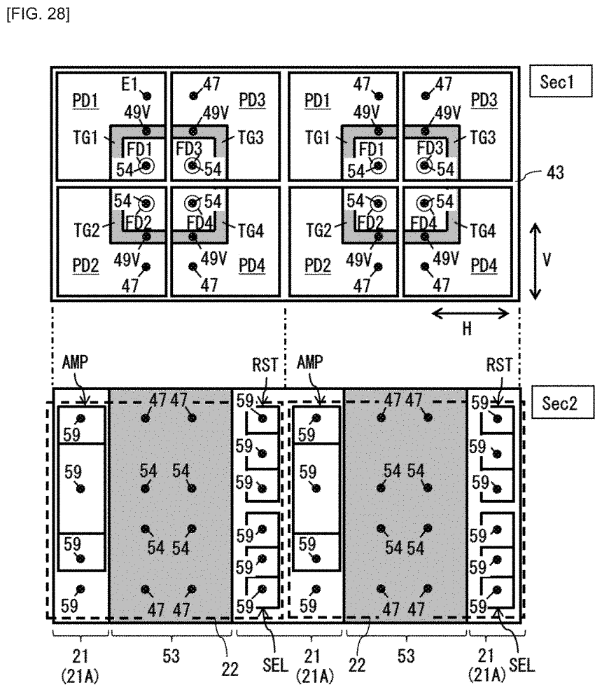

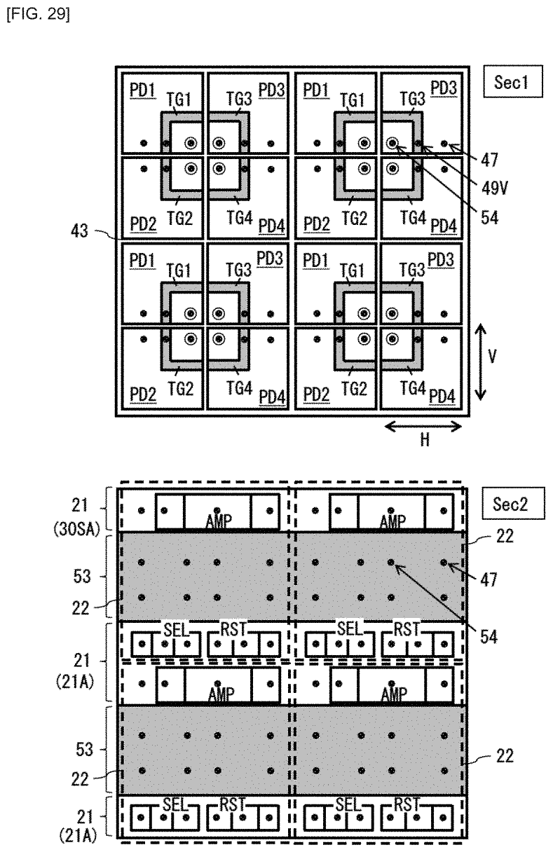

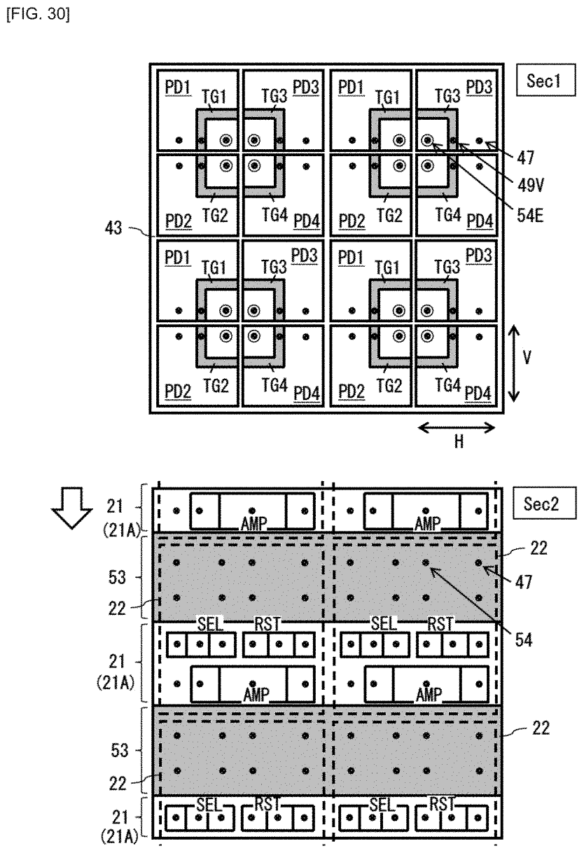

Each of FIGS. 28 and 29 illustrates an example of a cross-sectional configuration of an imaging unit (e.g., the imaging unit 1A) according to a modification example (a modification example 3) of the first to fifth embodiments described above in the horizontal direction. Each of FIGS. 29 and 30 illustrates a modification example of the cross-sectional configuration in FIG. 14.

In the present modification example, the first substrate 10 includes, for each of the sensor pixels 12, the photodiode PD, the transfer transistor TR electrically coupled to the photodiode PD, and the floating diffusion FD that temporarily holds electric charge outputted from the photodiode PD through the transfer transistor TR. Accordingly, in the present modification example, the through wiring line 54 is provided for each of the sensor pixels 12.

In the present modification example, the first substrate 10 includes the element separation section 43 that separates the photodiode PD and the transfer transistor TR for each of the sensor pixels 12. The element separation section 43 completely surrounds the sensor pixels 12 as viewed from the normal direction of the semiconductor substrate 11 and electrically separates the sensor pixels 12 adjacent to each other. The second substrate 20 includes the readout circuit 22 for every four sensor pixels 12 as in the first embodiment described above.

In the present modification example, the plurality of through wiring lines 54 and the plurality of through wiring lines 47 are disposed side by side in a strip shape in the first direction V within the plane of the first substrate 10 as illustrated in each of FIGS. 28 and 29. It is to be noted that each of FIGS. 28 and 29 exemplifies a case where the plurality of through wiring lines 54 and the plurality of through wiring lines 47 are disposed side by side in two rows in the first direction V. The first direction V is parallel with one (e.g., the column direction) of two arrangement directions (e.g., the row direction and the column direction) of the plurality of sensor pixels 12 disposed in a matrix. In the four sensor pixels 12 that share the readout circuit 22, the four floating diffusions FD are disposed close to each other, for example, with the element separation section 43 interposed in between. In the four sensor pixels 12 that share the readout circuit 22, the four transfer gates TG are disposed to surround the four floating diffusions FD and the four transfer gates TG form, for example, an annular shape.

### 6-4. Modification Example 4

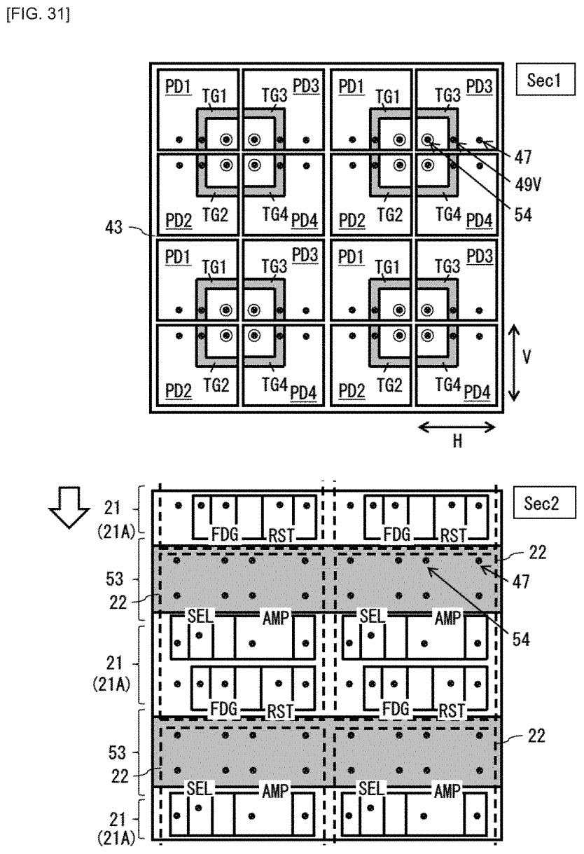

FIG. 30 illustrates an example of a cross-sectional configuration of an imaging unit (e.g., the imaging unit 1A) according to a modification example (a modification example 4) of the first to fifth embodiments described above in the vertical direction. FIG. 31 illustrates another example of a cross-sectional configuration of an imaging unit (e.g., the imaging unit 1A) according to a modification example (a modification example 3) of the first to fifth embodiments described above in the vertical direction. The diagram on the upper side of each of FIGS. 30 and 31 is a modification example of a cross-sectional configuration taken along the cross section Sec1 in FIG. 7 and the diagram on the lower side of FIG. 30 is a modification example of a cross-sectional configuration taken along the cross section Sec2 in FIG. 7. It is to be noted that a diagram illustrating a modification example of the front surface configuration of the semiconductor substrate 11 in FIG. 7 is superimposed on a diagram illustrating the modification example of the cross-sectional configuration taken along the cross section Sec1 in FIG. 7 and the insulating layer 46 is omitted in the cross-sectional view on the upper side of each of FIGS. 30 and 31. In addition, a diagram illustrating a modification example of the front surface configuration of the semiconductor substrate 21 is superimposed on a diagram illustrating the modification example of the cross-sectional configuration taken along the cross section Sec2 in FIG. 7 in the cross-sectional view on the lower side of each of FIGS. 30 and 31.

As illustrated in FIGS. 30 and 31, the plurality of through wiring lines 54, the plurality of through wiring lines 48, and the plurality of through wiring lines 47 (a plurality of dots disposed in a matrix in the diagram) are disposed side by side in a strip shape in the first direction V (the left/right direction in FIGS. 30 and 31) within the plane of the first substrate 10. It is to be noted that each of FIGS. 30 and 31 exemplifies a case where the plurality of through wiring lines 54, the plurality of through wiring lines 48, and the plurality of through wiring lines 47 are disposed side by side in two rows in the first direction V. In the four sensor pixels 12 that share the readout circuit 22, the four floating diffusions FD are disposed close to each other, for example, with the element separation section 43 interposed in between. In the four sensor pixels 12 that share the readout circuit 22, the four transfer gates TG (TG1, TG2, TG3, and TG4) are disposed to surround the four floating diffusions FD and the four transfer gates TG form, for example, an annular shape.

The insulating layer 53 includes a plurality of blocks extending in the first direction V. The semiconductor substrate 21 extends in the first direction V and includes the plurality of island-shaped blocks 21A disposed side by side in the second direction H orthogonal to the first direction V with the insulating layer 53 interposed in between. Each of the blocks 21A is provided, for example, with the reset transistor RST, the amplification transistor AMP, and the selection transistor SEL. The one readout circuit 22 that is shared by the four sensor pixels 12 is not disposed, for example, to be squarely opposed to the four sensor pixels 12, but disposed to shift in the second direction H.

In FIG. 30, the one readout circuit 22 shared by the four sensor pixels 12 includes the reset transistor RST, the amplification transistor AMP, and the selection transistor SEL in a region obtained by shifting, in the first direction V, the region opposed to the four sensor pixels 12 on the second substrate 20. The one readout circuit 22 shared by the four sensor pixels 12 includes, for example, the amplification transistor AMP, the reset transistor RST, and the selection transistor SEL in in the one block 21A.

In FIG. 31, the one readout circuit 22 shared by the four sensor pixels 12 includes the reset transistor RST, the amplification transistor AMP, the selection transistor SEL, and the FD transfer transistor FDG in a region obtained by shifting, in the first direction V, the region opposed to the four sensor pixels 12 on the second substrate 20. The one readout circuit 22 shared by the four sensor pixels 12 includes, for example, the amplification transistor AMP, the reset transistor RST, the selection transistor SEL, and the FD transfer transistor FDG in in the one block 21A.

In the present modification example, the one readout circuit 22 that is shared by the four sensor pixels 12 is not disposed, for example, to be squarely opposed to the four sensor pixels 12, but disposed to shift from the position opposed squarely opposed to the four sensor pixels 12 in the second direction H. In such a case, it is possible to shorten the wiring line 25 or it is possible to omit the wiring line 25 and cause the source of the amplification transistor AMP and the drain of the selection transistor SEL to include a common impurity region. As a result, it is possible to reduce the size of the readout circuit 22 or increase the size of another component in the readout circuit 22.

### 6-5. Modification Example 5

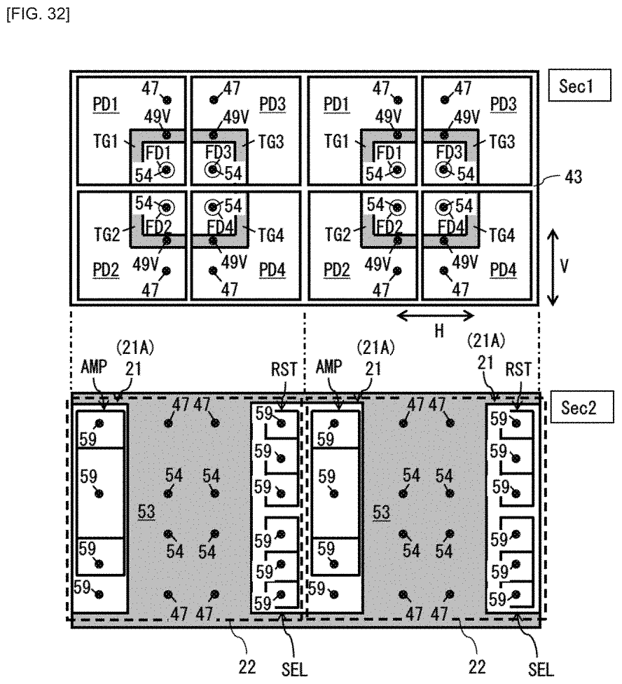

FIG. 32 illustrates an example of a cross-sectional configuration of an imaging unit (e.g., the imaging unit 1A) according to a modification example (a modification example 5) of the modification example 3 described above in the horizontal direction. FIG. 32 illustrates a modification example of the cross-sectional configuration in FIG. 28.

In the present modification example, the semiconductor substrate 21 includes the plurality of island-shaped blocks 21A disposed side by side in the first direction V and the second direction H with the insulating layer 53 interposed in between. Each of the blocks 21A is provided, for example, with one set of reset transistor RST, amplification transistor AMP, and selection transistor SEL. In such a case, it is possible to cause the insulating layer 53 to suppress the crosstalk between the readout circuits 22 adjacent to each other, making it possible to suppress image quality degradation due to a decrease in resolution and color mixing on a reproduced image.

### 6-6. Modification Example 6

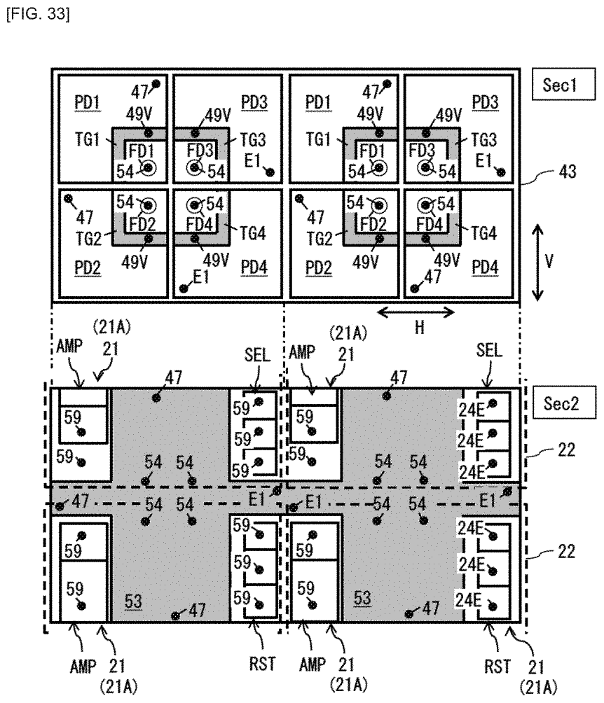

FIG. 33 illustrates an example of a cross-sectional configuration of an imaging unit (e.g., the imaging unit 1A) according to a modification example (a modification example 6) of the modification example 3 described above in the horizontal direction. FIG. 33 illustrates a modification example of the cross-sectional configuration in FIG. 28.

In the present modification example, the one readout circuit 22 that is shared by the four sensor pixels 12 is not disposed, for example, to be squarely opposed to the four sensor pixels 12, but disposed to shift in the first direction V. Further, as in the modification example 5, in the present modification example, the semiconductor substrate 21 includes the plurality of island-shaped blocks 21A disposed side by side in the first direction V and the second direction H with the insulating layer 53 interposed in between. Each of the blocks 21A is provided, for example, with one set of reset transistor RST, amplification transistor AMP, and selection transistor SEL. In the present modification example, the plurality of through wiring lines 47 and the plurality of through wiring lines 54 are further disposed even in the second direction H. Specifically, the plurality of through wiring lines 47 is disposed between the four through wiring lines 54 that share the certain readout circuit 22 and the four through wiring lines 54 that share the other readout circuit 22 adjacent to the certain readout circuit 22 in the second direction H. In such a case, it is possible to cause the insulating layer 53 and the through wiring line 47 to suppress the crosstalk between the readout circuits 22 adjacent to each other, making it possible to suppress image quality degradation due to a decrease in resolution and color mixing on a reproduced image.

### 6-7. Modification Example 7

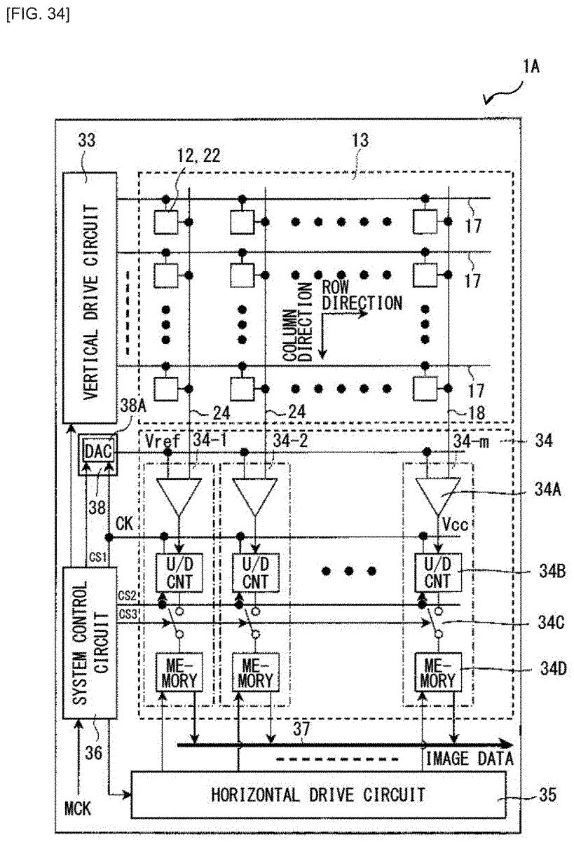

FIG. 34 illustrates an example of a circuit configuration of an imaging unit (e.g., the imaging unit 1A) according to a modification example (a modification example 7) of the first to fifth embodiments and the modification examples 1 to 6 described above. The imaging unit 1A according to the present modification example is a CMOS image sensor mounted with column-parallel ADC.

As illustrated in FIG. 34, the imaging unit 1A according to the present modification example includes the vertical drive circuit 33, the column signal processing circuit 34, a reference voltage supply section 38, the horizontal drive circuit 35, a horizontal output line 37, and the system control circuit 36 in addition to the pixel region 13 in which the plurality of sensor pixels 12 is two-dimensionally disposed in a matrix (a matrix shape). Each of the plurality of sensor pixels 12 includes a photoelectric conversion element.

In this system configuration, on the basis of a master clock MCK, the system control circuit 36 generates a clock signal, a control signal, or the like that serves as a criterion for an operation of the vertical drive circuit 33, the column signal processing circuit 34, the reference voltage supply section 38, the horizontal drive circuit 35, and the like, and provides the clock signal, the control signal, or the like to the vertical drive circuit 33, the column signal processing circuit 34, the reference voltage supply section 38, the horizontal drive circuit 35, and the like.

In addition, the vertical drive circuit 33 is formed on the first substrate 10 along with each of the sensor pixels 12 of the pixel region 13 and is further formed even on the second substrate 20 on which the readout circuit 22 is formed. The column signal processing circuit 34, the reference voltage supply section 38, the horizontal drive circuit 35, the horizontal output line 37, and the system control circuit 36 are formed on the third substrate 30.

It is possible to use, as the sensor pixel 12, for example, a component including, in addition to the photodiode PD, the transfer transistor TR that transfers electric charge obtained by photoelectric conversion by the photodiode PD to the floating diffusion FD, although not illustrated here. In addition, it is possible to use, as the readout circuit 22, for example, a component having a three-transistor configuration in which the reset transistor RST that controls the electric potential of the floating diffusion FD, the amplification transistor AMP that outputs a signal corresponding to the electric potential of the floating diffusion FD, and the selection transistor SEL for selecting a pixel are included, although not illustrated here.

In the pixel region 13, the sensor pixels 12 are two-dimensionally disposed. With respect to this m-row and n-column pixel disposition, the pixel drive lines 23 are wired for the respective rows and the vertical signal lines 24 are wired for the respective columns. One end of each of the plurality of pixel drive lines 23 is coupled to a corresponding output end of the rows of the vertical drive circuit 33. The vertical drive circuit 33 includes a shift register or the like and controls the row address and the row scanning of the pixel region 13 through the plurality of pixel drive lines 23.

The column signal processing circuit 34 includes, for example, ADCs (analog-to-digital conversion circuits) 34-1 to 34-m provided for the respective pixel columns or for the respective vertical signal lines 24 of the pixel region 13. The column signal processing circuit 34 converts analog signals outputted column by column from the respective sensor pixels 12 of the pixel region 13 into digital signals and outputs the digital signals.

The reference voltage supply section 38 includes, for example, DAC (digital-to-analog conversion circuit) 38A as a means for generating a reference voltage Vref of a so-called ramp (RAMP) waveform having a level that changes in an inclined manner as time elapses. It is to be noted that the means for generating the reference voltage Vref of the ramp waveform is not limited to the DAC 38A.

Under the control of a control signal CS1 provided from the system control circuit 36, the DAC 38A generates the reference voltage Vref of the ramp waveform on the basis of a clock CK provided from the system control circuit 36 and supplies the generated reference voltage Vref to each of the ADCs 34-1 to 34-m of the column signal processing circuit 34.

It is to be noted that each of the ADCs 34-1 to 34-m is configured to selectively perform an AD conversion operation corresponding to each operation mode of a normal frame rate mode in a progressive scanning system for reading information on all of the sensor pixels 12 and a high-speed frame rate mode for setting exposure time of the sensor pixel 12 to 1/N to increase a frame rate by N times, for example, by twice, as compared with the time of the normal frame rate mode. This switching between the operation modes is executed on the basis of control performed by control signals CS2 and CS3 provided from the system control circuit 36. In addition, instruction information for switching the respective operation modes of the normal frame rate mode and the high-speed frame rate mode is provided from an external system controller (not illustrated) to the system control circuit 36.

All of the ADCs 34-1 to 34-m have the same configuration. The ADC 34-m is described here as an example. The ADC 34-m includes a comparator 34A, an up/down counter (referred to as U/D CNT in the diagram) 34B that is, for example, a number counting means, a transfer switch 34C, and a memory 34D.

The comparator 34A compares a signal voltage Vx of the vertical signal line 24 corresponding to a signal outputted from each of the sensor pixels 12 in an n-th column of the pixel region 13 and the reference voltage Vref of the ramp waveform supplied from the reference voltage supply section 38. For example, in a case where the reference voltage Vref is larger than the signal voltage Vx, an output Vco enters an “H” level. In a case where the reference voltage Vref is the signal voltage Vx or less, the output Vco enters an “L” level.

An up/down counter 34B is an asynchronous counter. Under the control of the control signal CS2 provided from the system control circuit 36, the up/down counter 34B is provided with the clock CK from the system control circuit 36 concurrently with DAC 18A. The up/down counter 34B performs down (DOWN)-counting or up (UP)-counting in synchronization with the clock CK, thereby measuring a comparison period from the start of a comparison operation to the end of the comparison operation in the comparator 34A.

Specifically, in a reading operation of signals from the one sensor pixel 12, the down-counting is performed in the normal frame rate mode upon a first reading operation, thereby measuring comparison time upon the first reading. The up-counting is performed upon a second reading operation, thereby measuring comparison time upon the second reading.

Meanwhile, while holding a count result for the sensor pixel 12 in a certain row as it is in the high-speed frame rate mode, the down-counting is subsequently performed for the sensor pixel 12 in the next row upon a first reading operation from the previous count result, thereby measuring comparison time upon the first reading. The up-counting is performed upon a second reading operation, thereby measuring comparison time upon the second reading.

Under the control by the control signal CS3 provided from the system control circuit 36, the transfer switch 34C is turned on (closed) in the normal frame rate mode upon completion of the counting operation of the up/down counter 34B for the sensor pixel 12 in a certain row and transfers the count results of the up/down counter 34B to the memory 34D.

Meanwhile, for example, in the high-speed frame rate of N=2, the transfer switch 34C remains off (open) upon completion of the counting operation of the up/down counter 34B for the sensor pixel 12 in a certain row and is subsequently turned on upon completion of the counting operation of the up/down counter 34B for the sensor pixel 12 in the next row. The transfer switch 34C transfers the count results of the up/down counter 34B for the vertical two pixels to the memory 34D.

In this way, analog signals supplied for respective columns from the respective sensor pixels 12 of the pixel region 13 through the vertical signal lines 24 are converted into N-bit digital signals by respective operations of the comparators 34A and the up/down counters 34B in the ADCs 34-1 to 34-m and are stored in the memories 34D.

The horizontal drive circuit 35 includes a shift register or the like and controls the column address and the column scanning of the ADCs 34-1 to 34-m in the column signal processing circuit 34. Under the control of the horizontal drive circuit 35, the N-bit digital signals subjected to the AD conversion in the respective ADCs 34-1 to 34-m are read out to the horizontal output line 37 in order and outputted as imaging data through the horizontal output line 37.

It is to be noted that it is also possible to provide, in addition to the components described above, a circuit or the like that performs various kinds of signal processing on the imaging data outputted through the horizontal output line 37, although not illustrated in particular because there is no direct relationship with the present disclosure.

It is possible in the imaging unit 1A mounted with the column-parallel ADC according to the present modification example having the configuration described above to selectively transfer the count results of the up/down counter 34B to the memory 34D through the transfer switch 34C. This makes it possible to independently control the counting operation of the up/down counter 34B and the reading operation of the count results of the up/down counter 34B to the horizontal output line 37.

### 6-8. Modification Example 8

FIG. 35 illustrates an example in which the imaging unit in FIG. 34 includes three substrates (the first substrate 10, the second substrate 20, and the third substrate 30) that are stacked. In the present modification example, the pixel region 13 is formed in a middle portion of the first substrate 10. the vertical drive circuit 33 is formed around the pixel region 13. The pixel region 13 includes the plurality of sensor pixels 12 is formed. In addition, a readout circuit region 15 is formed in a middle portion of the second substrate 20. The vertical drive circuit 33 is formed around the readout circuit region 15. The readout circuit region 15 includes the plurality of readout circuits 22. In the third substrate 30, the column signal processing circuit 34, the horizontal drive circuit 35, the system control circuit 36, the horizontal output line 37, and the reference voltage supply section 38 are formed. This eliminates an increase in chip size and eliminates the prevention of one pixel from having smaller area due to the structure of electrically coupling substrates to each other as in the embodiment described above and the modification examples thereof. As a result, it is possible to provide the imaging unit 1A having a three-layer structure that does not prevent one pixel from having smaller area while maintaining a chip size equivalent to an existing chip size. It is to be noted that the vertical drive circuit 33 may be formed on the first substrate 10 alone or may be formed on the second substrate 20 alone.

### 6-9. Modification Example 9

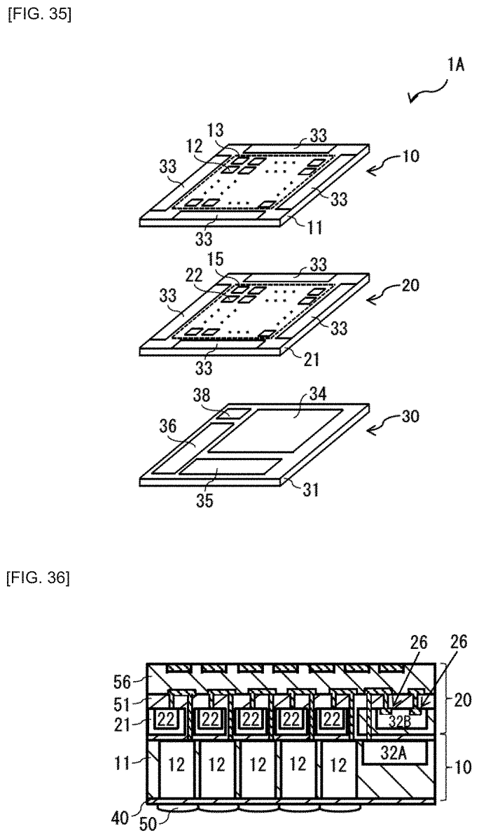

FIG. 36 illustrates an example of a cross-sectional configuration of an imaging unit (e.g., the imaging unit 1A) according to a modification example (a modification example 9) of the first to fifth embodiments described above and the modification examples 1 to 8 thereof. In the first to fourth embodiments described above, the modification examples 1 to 8 thereof, and the like, the imaging unit 1A includes three substrates (the first substrate 10, the second substrate 20, and the third substrate 30) that are stacked. However, as with the imaging unit 1A according to the fifth embodiment described above, an imaging unit may include two substrates (the first substrate 10 and the second substrate 20) that are stacked. In this case, the logic circuit 32 may be formed separately on the first substrate 10 and the second substrate 20, for example, as illustrated in FIG. 36. Here, a circuit 32A of the logic circuit 32 is provided with a transistor having a gate structure in which a high dielectric constant film including a material (e.g., high-k) that is able to withstand a high temperature process and a metal gate electrode are stacked. The circuit 32A is provided on the first substrate 10 side. Meanwhile, in a circuit 32B provided on the second substrate 20 side, a low resistance region 26 that includes a silicide and is formed by using Salicide (Self Aligned silicide) process such as CoSi₂ and NiSi is formed on the surface of an impurity diffusion region in contact with a source electrode and a drain electrode. The low resistance region including a silicide is formed by using a compound of a material of a semiconductor substrate and metal. This makes it possible to use a high temperature process such as thermal oxidation in a case where the sensor pixel 12 is formed. In addition, it is possible to reduce contact resistance in a case where the low resistance region 26 including a silicide is provided on the surface of the impurity diffusion region in contact with the source electrode and the drain electrode in the circuit 32B of the logic circuit 32. The circuit 32B is provided on the second substrate 20 side. As a result, it is possible to increase the speed of an arithmetic operation in the logic circuit 32.

### 6-10. Modification Example 10

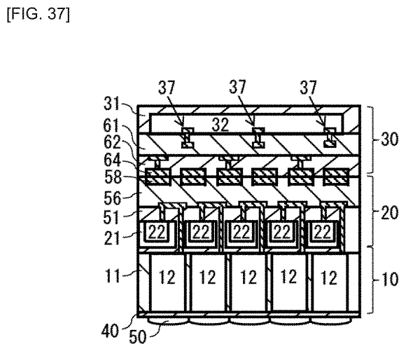

FIG. 37 illustrates a modification example of a cross-sectional configuration of the imaging unit 1A according to a modification example (a modification example 10) of any of the first to fourth embodiments described above and the modification examples 1 to 8 thereof. In the logic circuit 32 of the third substrate 30 according to any of the first to fourth embodiments described above and the modification examples 1 to 8 thereof, a low resistance region 37 that includes a silicide and is formed by using Salicide (Self Aligned silicide) process such as CoSi₂ and NiSi may be formed on the surface of an impurity diffusion region in contact with a source electrode and a drain electrode. This makes it possible to use a high temperature process such as thermal oxidation in a case where the sensor pixel 12 is formed. In addition, it is possible to reduce contact resistance in a case where the low resistance region 37 including a silicide is provided on the surface of the impurity diffusion region in contact with the source electrode and the drain electrode in the logic circuit 32. As a result, it is possible to increase the speed of an arithmetic operation in the logic circuit 32.

It is to be noted that the electric conductivity type may be opposite in the first to fifth embodiments described above and the modification examples 1 to 10 thereof. For example, in the descriptions of the first to fifth embodiments described above and the modification examples 1 to 10 thereof, the p-type may be read as the n-type and the n-type may be read as the p-type. Even in such a case, it is possible to obtain effects similar to those of the first to fifth embodiments described above and the modification examples 1 to 10 thereof.

### 7. Application Examples

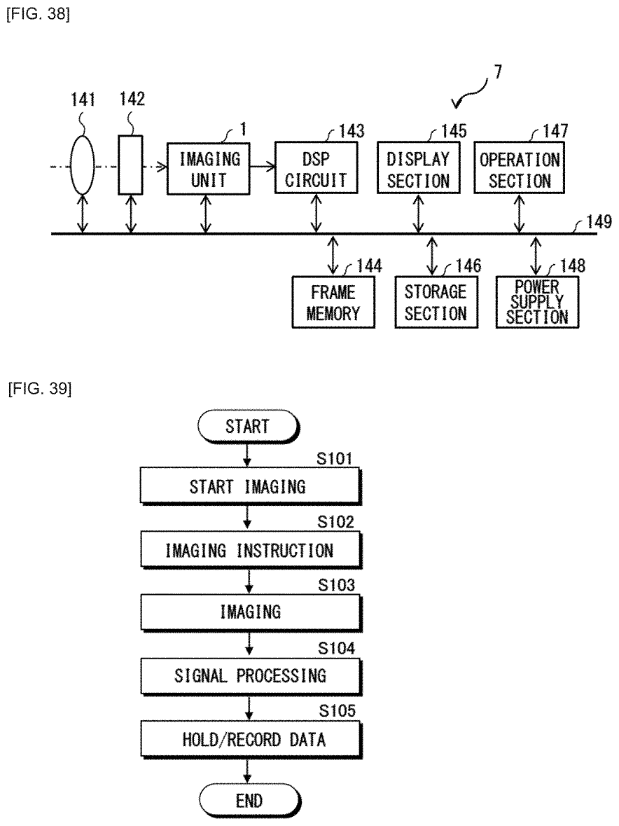

FIG. 38 illustrates an example of a schematic configuration of an imaging system 7 including the imaging unit (e.g., the imaging unit 1A) according to any of the first to fifth embodiments described above and the modification examples 1 to 10 thereof.

The imaging system 7 is an electronic apparatus including, for example, an imaging apparatus such as a digital still camera or a video camera, a portable terminal apparatus such as a smartphone or a tablet-type terminal, or the like. The imaging system 7 includes, for example, an optical system 141, a shutter unit 142, the imaging unit 1A, a DSP circuit 143, a frame memory 144, a display section 145, a storage section 146, an operation section 147, and a power supply section 148. In the imaging system 7, the shutter unit 142, the imaging unit 1A, the DSP circuit 143, the frame memory 144, the display section 145, the storage section 146, the operation section 147, and the power supply section 148 are coupled to each other through a bus line 149.

The imaging unit 1A outputs image data corresponding to incident light. The optical system 141 includes one or more lenses and guides light (incident light) from a subject to the imaging unit 1A to form an image on a light receiving surface of the imaging unit 1A. The shutter unit 142 is disposed between the optical system 141 and the imaging unit 1A and controls a period in which the imaging unit 1A is irradiated with light and a period in which light is blocked under the control of the operation section 147. The DSP circuit 143 is a signal processing circuit that processes a signal (image data) outputted from the imaging unit 1A. The frame memory 144 temporarily holds the image data processed by the DSP circuit 143 in a frame unit. The display section 145 includes, for example, a panel-type display device such as a liquid crystal panel or an organic EL (Electro Luminescence) panel and displays a moving image or a still image captured by the imaging unit 1A. The storage section 146 records image data of a moving image or a still image captured by the imaging unit 1A in a recording medium such as a semiconductor memory or a hard disk. The operation section 147 issues an operation instruction for various functions of the imaging system 7 in accordance with an operation by a user. The power supply section 148 appropriately supplies various kinds of power for operation to the imaging unit 1A, the DSP circuit 143, the frame memory 144, the display section 145, the storage section 146, and the operation section 147 that are supply targets.

Next, an imaging procedure in the imaging system 7 is described.

FIG. 39 illustrates an example of a flowchart of an imaging operation in the imaging system 7. A user issues an instruction to start imaging by operating the operation section 147 (step S101). The operation section 147 then transmits an imaging instruction to the imaging unit 1A (step S102). The imaging unit 1A (specifically, the system control circuit 36) executes imaging in a predetermined imaging scheme upon receiving the imaging instruction (step S103).

The imaging unit 1A outputs light (image data) formed on the light receiving surface through the optical system 141 and the shutter unit 142 to the DSP circuit 143. Here, the image data refers to data for all of the pixels of pixel signals generated on the basis of electric charge temporarily held in the floating diffusion FD. The DSP circuit 143 performs predetermined signal processing (e.g., noise reduction processing or the like) on the basis of the image data inputted from the imaging unit 1A (step S104). The DSP circuit 143 causes the frame memory 144 to hold the image data subjected to the predetermined signal processing and the frame memory 144 causes the storage section 146 to store the image data (step S105). In this way, the imaging in the imaging system 7 is performed.

In the present application example, the imaging unit 1A is applied to the imaging system 7. This allows the imaging unit 1A to be smaller or higher in definition. This makes it possible to provide the small or high-definition imaging system 7.

### 8. Practical Application Examples

### Practical Application Example 1

The technology (the present technology) according to the present disclosure is applicable to a variety of products. For example, the technology according to the present disclosure may be achieved as a device mounted on any type of mobile body such as an automobile, an electric vehicle, a hybrid electric vehicle, a motorcycle, a bicycle, a personal mobility, an airplane, a drone, a vessel, or a robot.

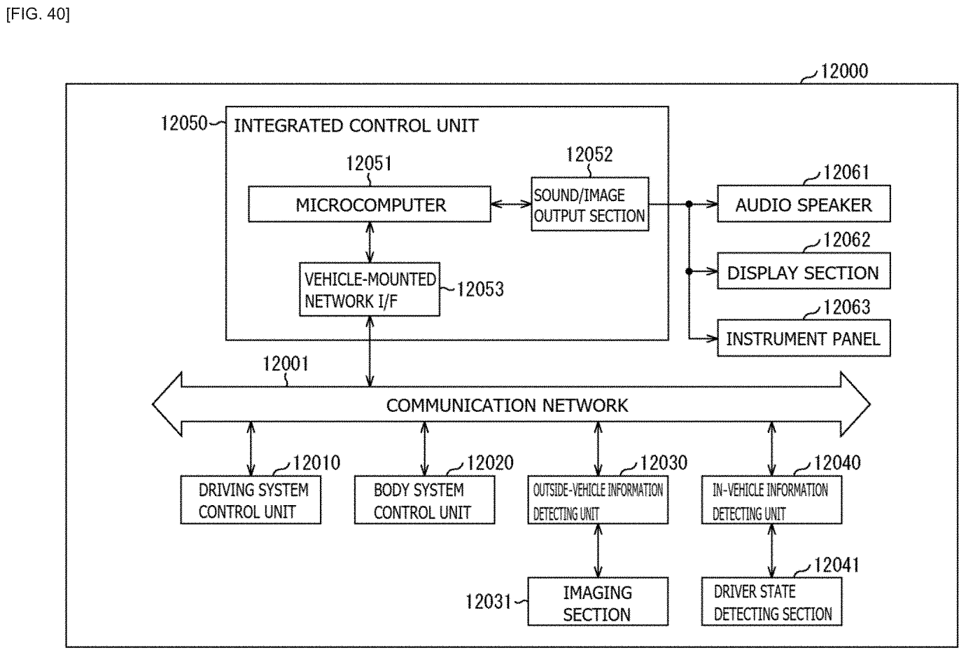

FIG. 40 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 40, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automatic driving, which makes the vehicle to travel autonomously without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 40, an audio speaker 12061, a display section 12062, and an instrument panel 12063 are illustrated as the output device. The display section 12062 may, for example, include at least one of an on-board display and a head-up display.

FIG. 41 is a diagram depicting an example of the installation position of the imaging section 12031.

In FIG. 41, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 41 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automatic driving that makes the vehicle travel autonomously without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

The above has described the example of the mobile body control system to which the technology according to the present disclosure may be applied. The technology according to the present disclosure may be applied to the imaging section 12031 among the components described above. Specifically, the imaging units 1A according to the embodiment described above and modification examples thereof are each applicable to the imaging section 12031. The application of the technology according to the present disclosure to the imaging section 12031 makes it possible to obtain a high-definition shot image with less noise and it is thus possible to perform highly accurate control using the shot image in the mobile body control system.

### Practical Application Example 2

FIG. 42 is a view depicting an example of a schematic configuration of an endoscopic surgery system to which the technology according to an embodiment of the present disclosure (present technology) can be applied.

In FIG. 42, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

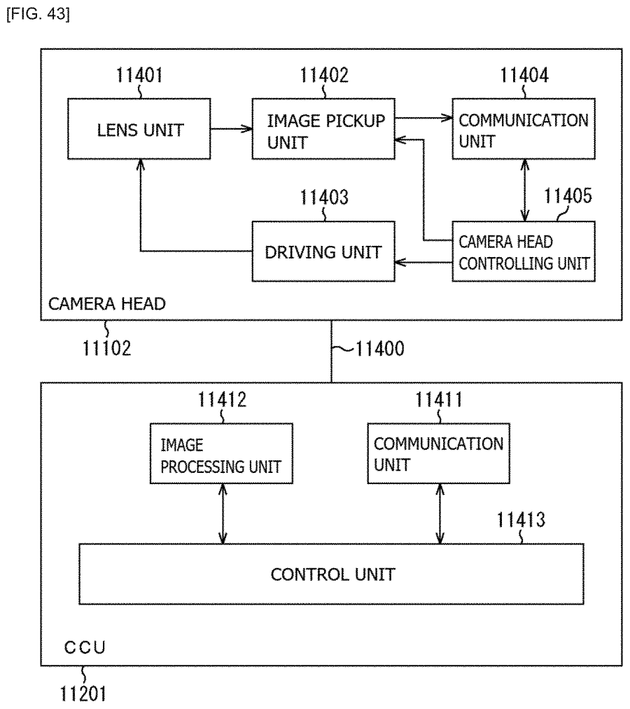

FIG. 43 is a block diagram depicting an example of a functional configuration of the camera head 11102 and the CCU 11201 depicted in FIG. 42.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

The above has described the example of the endoscopic surgery system to which the technology according to the present disclosure may be applied. The technology according to the present disclosure may be favorably applied to the image pickup unit 11402 provided to the camera head 11102 of the endoscope 11100 among the components described above. The application of the technology according to the present disclosure to the image pickup unit 11402 makes it possible to achieve the downsizing or higher definition of the image pickup unit 11402 and it is thus possible to provide the small or high-definition endoscope 11100.

Although the present disclosure has been described above with reference to the first to fifth embodiments, the modification examples 1 to 10 thereof, the application example thereof, and the practical application examples thereof, the present disclosure is not limited to the embodiment and the like described above. A variety of modifications are possible. For example, in the embodiment or the like described above, description has been given by using an imaging unit as a specific example of the semiconductor device 1 having a three-dimensional structure, but this is not limitative. The present technology is applicable to any three-dimensional stacked semiconductor device subjected to large scale integration (LSI).

It is to be noted that the effects described herein are merely illustrative. The effects according to the present disclosure are not limited to the effects described herein. The present disclosure may have effects other than the effects described herein.

It is to be noted that the present disclosure may also have configurations as follows. According to the present technology having the following configurations, the wiring structure at least partially having the stack region makes it possible to form a wiring line between the first semiconductor substrate and the second semiconductor substrate. This decreases, for example, the number of through wiring lines extending in the normal direction of the first semiconductor substrate. The semiconductor layer and the metal layer are stacked in the stack region. Alternatively, the total height of the through wiring lines decreases. This makes it possible to reduce the parasitic capacitance.

(1)

An imaging unit including:

a first substrate including a sensor pixel on a first semiconductor substrate, the sensor pixel performing photoelectric conversion;

a second substrate including a readout circuit on a second semiconductor substrate, the readout circuit outputting a pixel signal based on electric charge outputted from the sensor pixel, the second substrate being stacked on the first substrate; and

a wiring line extending between the first semiconductor substrate and the second semiconductor substrate in a direction parallel with the first semiconductor substrate, the wiring line at least partially having a stack region in which a semiconductor layer and a metal layer are stacked.

(2)

The imaging unit according to (1), in which the semiconductor layer is formed by using a polymer, an amorphous solid, or a single crystal of Si, Ge, SiGe, SiC, ZnSe, GaAs, GaP, InP, InN, GaN, InGaN, GaAlAs, IGaAs, GaInNAs, InGaAlP, ZnO, IGZO, MoS₂, MoSe₂, MoTe₂, WS₂, WSe₂, WTe₂, ZrS₂, ZrSe₂, ZrTe₂, HfS₂, HfSe₂, HfTe₂, graphene, phospherene, and a carbon nanotube.

(3)

The imaging unit according to (1) or (2), in which the metal layer is formed by using one or two or more of tungsten (W), aluminum (Al), cobalt (Co), nickel (Ni), and platinum (Pt) or a compound of any of the metals and silicon (Si).

(4)

The imaging unit according to any of (1) to (3), in which the semiconductor layer and the metal layer are stacked in the stack region in this order from the first semiconductor substrate side.

(5)

The imaging unit according to any of (1) to (4), in which

the second semiconductor substrate has an opening that extends through the second semiconductor substrate in a stack direction, and

the stack region of the wiring line is provided at a position corresponding to at least the opening.

(6)

The imaging unit according to (5), in which

a stacked body including the first substrate and the second substrate further includes an interlayer insulating film between the first semiconductor substrate and the second semiconductor substrate and in the opening, and

the wiring line is provided in the interlayer insulating film.

(7)

The imaging unit according to (6), in which

the stacked body including the first substrate and the second substrate further includes a first through wiring line that is provided in the interlayer insulating film, the first through wiring line extending through the opening, and

the first substrate and the second substrate are electrically coupled by the first through wiring line.

(8)

The imaging unit according to any of (1) to (7), in which

the sensor pixel includes a photoelectric conversion element, a transfer transistor, and a floating diffusion, the transfer transistor being electrically coupled to the photoelectric conversion element, the floating diffusion temporarily holding electric charge outputted from the photoelectric conversion element through the transfer transistor, and

the readout circuit includes a reset transistor, an amplification transistor, and a selection transistor, the reset transistor resetting an electric potential of the floating diffusion to a predetermined position, the amplification transistor generating, as the pixel signal, a signal of a voltage corresponding to a level of the electric charge held in the floating diffusion, the selection transistor controlling a timing of outputting the pixel signal from the amplification transistor.

(9)

The imaging unit according to (8), in which the wiring line is electrically coupled to a gate of the transfer transistor through a semiconductor via.

(10)

The imaging unit according to any of (1) to (9), further including a third substrate including a signal processing circuit on a third semiconductor substrate, the signal processing circuit processing the pixel signal, in which

the first substrate, the second substrate, and the third substrate are stacked in this order.

(11)

The imaging unit according to (10), in which the wiring line is electrically coupled to the signal processing circuit through a metal via a semiconductor via.

(12)

The imaging unit according to any of (8) to (11), in which the wiring line is directly coupled to a gate of the transfer transistor.

(13)

The imaging unit according to any of (8) to (12), in which the wiring line also serves as a gate of the transfer transistor.

(14)

A method of manufacturing an imaging unit, the method including:

forming a first interlayer insulating film on a first semiconductor substrate including a sensor pixel that performs photoelectric conversion;

forming a semiconductor layer on the first interlayer insulating film, the semiconductor layer extending in a direction parallel with the first semiconductor substrate;

forming a second interlayer insulating film on the first interlayer insulating film and the semiconductor layer;

forming a second semiconductor substrate including a readout circuit that outputs a pixel signal based on electric charge outputted from the sensor pixel;

forming an opening in a predetermined region on the second semiconductor substrate, the opening extending through the second semiconductor substrate to the semiconductor layer; and

forming a wiring line by stacking a metal layer on the semiconductor layer in the opening, the wiring line at least partially having a stack region of the semiconductor layer and the metal layer.

(15)

The method of manufacturing the imaging unit according to (14), in which a metal film is formed on the semiconductor layer by sputtering and the metal film is then silicidized by heat treatment to form the metal layer.

(16)

The method of manufacturing the imaging unit according to (14) or (15), in which the metal layer is formed on the semiconductor layer by using a chemical vapor growth (CVD) method.

(17)

A semiconductor device including:

a first device layer;

a second device layer; and

a wiring line provided between the first device layer and the second device layer, the wiring line at least partially having a stack region in which a semiconductor layer and a metal layer are stacked.

(18)

The semiconductor device according to (17), in which the wiring line has the stack region in a region, the second device layer not being located at least above the region.

(19)

The semiconductor device according to (17) or (18), in which the wiring line is electrically coupled to the first device layer through a semiconductor via.

(20)

The semiconductor device according to any of (17) to (19), in which the wiring line is electrically coupled to the second device layer through a metal via or a semiconductor via.

This application claims the priority on the basis of Japanese Patent Application No. 2019-048552 filed with Japan Patent Office on Mar. 15, 2019, the entire contents of which are incorporated in this application by reference.

It should be understood by those skilled in the art that various modifications, combinations, sub-combinations, and alterations may occur depending on design requirements and other factors insofar as they are within the scope of the appended claims or the equivalents thereof.

1. An imaging unit comprising:
a first substrate including a sensor pixel on a first semiconductor substrate, the sensor pixel performing photoelectric conversion;
a second substrate including a readout circuit on a second semiconductor substrate, the readout circuit outputting a pixel signal based on electric charge outputted from the sensor pixel, the second substrate being stacked on the first substrate; and
a wiring line extending between the first semiconductor substrate and the second semiconductor substrate in a direction parallel with the first semiconductor substrate, the wiring line at least partially having a stack region in which a semiconductor layer and a metal layer are stacked.

2. The imaging unit according to claim 1, wherein the semiconductor layer is formed by using a polymer, an amorphous solid, or a single crystal of Si, Ge, SiGe, SiC, ZnSe, GaAs, GaP, InP, InN, GaN, InGaN, GaAlAs, IGaAs, GaInNAs, InGaAlP, ZnO, IGZO, MoS₂, MoSe₂, MoTe₂, WS₂, WSe₂, WTe₂, ZrS₂, ZrSe₂, ZrTe₂, HfS₂, HfSe₂, HfTe₂, graphene, phospherene, and a carbon nanotube.

3. The imaging unit according to claim 1, wherein the metal layer is formed by using one or two or more of tungsten (W), aluminum (Al), cobalt (Co), nickel (Ni), and platinum (Pt) or a compound of any of the metals and silicon (Si).

4. The imaging unit according to claim 1, wherein the semiconductor layer and the metal layer are stacked in the stack region in this order from the first semiconductor substrate side.

5. The imaging unit according to claim 1, wherein
the second semiconductor substrate has an opening that extends through the second semiconductor substrate in a stack direction, and
the stack region of the wiring line is provided at a position corresponding to at least the opening.

6. The imaging unit according to claim 5, wherein
a stacked body including the first substrate and the second substrate further includes an interlayer insulating film between the first semiconductor substrate and the second semiconductor substrate and in the opening, and
the wiring line is provided in the interlayer insulating film.

7. The imaging unit according to claim 6, wherein
the stacked body including the first substrate and the second substrate further includes a first through wiring line that is provided in the interlayer insulating film, the first through wiring line extending through the opening, and
the first substrate and the second substrate are electrically coupled by the first through wiring line.

8. The imaging unit according to claim 1, wherein
the sensor pixel includes a photoelectric conversion element, a transfer transistor, and a floating diffusion, the transfer transistor being electrically coupled to the photoelectric conversion element, the floating diffusion temporarily holding electric charge outputted from the photoelectric conversion element through the transfer transistor, and
the readout circuit includes a reset transistor, an amplification transistor, and a selection transistor, the reset transistor resetting an electric potential of the floating diffusion to a predetermined position, the amplification transistor generating, as the pixel signal, a signal of a voltage corresponding to a level of the electric charge held in the floating diffusion, the selection transistor controlling a timing of outputting the pixel signal from the amplification transistor.

9. The imaging unit according to claim 8, wherein the wiring line is electrically coupled to a gate of the transfer transistor through a semiconductor via.

10. The imaging unit according to claim 1, further comprising a third substrate including a signal processing circuit on a third semiconductor substrate, the signal processing circuit processing the pixel signal, wherein
the first substrate, the second substrate, and the third substrate are stacked in this order.

11. The imaging unit according to claim 10, wherein the wiring line is electrically coupled to the signal processing circuit through a metal via a semiconductor via.

12. The imaging unit according to claim 8, wherein the wiring line is directly coupled to a gate of the transfer transistor.

13. The imaging unit according to claim 8, wherein the wiring line also serves as a gate of the transfer transistor.

14. A method of manufacturing an imaging unit, the method comprising:
forming a first interlayer insulating film on a first semiconductor substrate including a sensor pixel that performs photoelectric conversion;
forming a semiconductor layer on the first interlayer insulating film, the semiconductor layer extending in a direction parallel with the first semiconductor substrate;
forming a second interlayer insulating film on the first interlayer insulating film and the semiconductor layer;
forming a second semiconductor substrate including a readout circuit that outputs a pixel signal based on electric charge outputted from the sensor pixel;
forming an opening in a predetermined region on the second semiconductor substrate, the opening extending through the second semiconductor substrate to the semiconductor layer; and
forming a wiring line by stacking a metal layer on the semiconductor layer in the opening, the wiring line at least partially having a stack region of the semiconductor layer and the metal layer.

15. The method of manufacturing the imaging unit according to claim 14, wherein a metal film is formed on the semiconductor layer by sputtering and the metal film is then silicidized by heat treatment to form the metal layer.

16. The method of manufacturing the imaging unit according to claim 14, wherein the metal layer is formed on the semiconductor layer by using a chemical vapor growth (CVD) method.

17. A semiconductor device comprising:
a first device layer;
a second device layer; and
a wiring line provided between the first device layer and the second device layer, the wiring line at least partially having a stack region in which a semiconductor layer and a metal layer are stacked.

18. The semiconductor device according to claim 17, wherein the wiring line has the stack region in a region, the second device layer not being located at least above the region.

19. The semiconductor device according to claim 17, wherein the wiring line is electrically coupled to the first device layer through a semiconductor via.

20. The semiconductor device according to claim 17, wherein the wiring line is electrically coupled to the second device layer through a metal via or a semiconductor via.
